(19) United States
(12) Patent Application Publication
(10) Pub. No.: US 2016/0358548 A1
(43) Pub. Date: Dec. 8, 2016

(54) THIN-FILM TRANSISTOR ARRAY DEVICE, EL DEVICE, SENSOR DEVICE, METHOD OF DRIVING THIN-FILM TRANSISTOR ARRAY DEVICE, METHOD OF DRIVING EL DEVICE, AND METHOD OF DRIVING SENSOR DEVICE

(71) Applicant: TOPPAN PRINTING CO., LTD., Taito-ku (JP)

(72) Inventor: Kunihiro MATSUDA, Taito-ku (JP)

(73) Assignee: TOPPAN PRINTING CO., LTD., Taito-ku (JP)

(21) Appl. No.: 15/238,829

(22) Filed: Aug. 17, 2016

Related U.S. Application Data
(63) Continuation of application No. PCT/JP2015/005335, filed on Feb. 6, 2015.

(30) Foreign Application Priority Data
Feb. 17, 2014 (JP) 2014-027852

(51) Int. Cl. G09G 3/3233; H01L 27/12; G09G 3/20

(52) U.S. Cl. CPC G09G 3/3233; G09G 3/2085; H01L 27/124; G09G 2310/0294; H01L 27/3262

(57) ABSTRACT

A thin film transistor array device includes row blocks each including selection rows, each selection row having at least one element circuit including a thin film transistor, and an element selection line, and a row block selection circuit including row block selection lines each corresponding to a respective one of the row blocks such that all the element selection lines in the respective one of the row blocks are parallelly connected to a respective one of the row block selection lines. The row block selection circuit applies, to the row block selection lines one by one, a selection level for selecting one row block from the row blocks from outside. The row block selection circuit further includes a switching circuit that switches between the element selection line and the row block selection line to change between a conduction state and a non-conduction state simultaneously for all the element selection lines.

### CROSS-REFERENCE TO RELATED APPLICATIONS

The present application is a continuation of International Application No. PCT/JP2015/053352, filed Feb. 6, 2015, which is based upon and claims the benefits of priority to Japanese Application No. 2014-027852, filed Feb. 17, 2014. The entire contents of these applications are incorporated herein by reference.

### BACKGROUND OF THE INVENTION

Field of the Invention

The technique of the present disclosure relates to a thin film transistor array device having a plurality of element selection lines, each connected to a thin film transistor, an EL device, a sensor device, a method of driving a thin film transistor array device, a method of driving an EL device, and a method of driving a sensor device.

Discussion of the Background

Electroluminescent (EL) devices include a plurality of EL elements, for example, arrayed in a matrix pattern. The plurality of EL elements are connected to respective pixel circuits. Each of the plurality of pixel circuits includes, for example, a drive transistor, a holding capacitor connected between a gate and a source of the drive transistor, a holding transistor connected to one of the electrodes of the holding capacitor, and a selection transistor connected to the other electrode of the holding capacitor.

The drain of the drive transistor of a pixel circuit is connected to a power supply driver through a power supply line to supply a drive current appropriate to a holding voltage of the holding capacitor to the EL element connected to the source of the drive transistor. The selection transistor of the pixel circuit is connected to one of the electrodes of the holding capacitor and a data line, while the holding transistor of the pixel circuit is connected to the other electrode of the holding capacitor and the drain of the drive transistor. The holding transistor and the selection transistor, which are selected by one selection driver, write a voltage corresponding to the difference between a writing level of the power supply line and a gradation level of the data line into the holding capacitor in an on state, and cause the holding capacitor to hold the voltage in an off state (e.g., refer to PTLs 1 and 2).

PTL 1: JP-A-2003-195810

PTL 2: JP-A-2013-114072

### SUMMARY OF THE INVENTION

According to one aspect of the present invention, a thin film transistor array device includes row blocks each including selection rows, each of the selection rows having at least one element circuit including a thin film transistor, and an element selection line connected to a gate of the thin film transistor, and a row block selection circuit including row block selection lines each corresponding to a respective one of the row blocks such that all the element selection lines in the respective one of the row blocks are parallelly connected to a respective one of the row block selection lines. The row block selection circuit applies, to the row block selection lines one by one, a selection level for selecting one row block from the row blocks from outside, the row block selection circuit further includes a switching circuit that switches between the element selection line and the row block selection line to change between a conduction state and a non-conduction state simultaneously for all the element selection lines, and the switching circuit permits row-block basis driving in the conduction state such that all the element circuits in the one row block selected by application of the selection level are simultaneously targeted to be driven and permits selection-row basis driving in the non-conduction state such that the row-block basis driving is prohibited and that all the element circuits in a respective one of the selection rows are simultaneously driven.

According to another aspect of the present invention, a method for driving a thin film transistor array device includes driving a switching circuit such that conduction is established between a row block selection line and an element selection line for all element selection lines, and applying, to row block selection lines one by one, a selection level for selecting one row block from row blocks such that a row block selection circuit simultaneously selects all element circuits in the one row block selected through application of the selection level. The thin film transistor array device includes row blocks each including selection rows such that each of the selection rows has at least one element circuit including a thin film transistor, and one element selection line connected to a gate of the thin film transistor, and a row block selection circuit including row block selection lines each corresponding to a respective one of the row blocks such that all the element selection lines in the respective one of the row blocks are parallelly connected to a respective one of the row block selection lines, and the row block selection circuit includes a switching circuit that switches between the row block selection line and the element selection line to change between a conduction state and a non-conduction state simultaneously for all the element selection lines.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a block diagram illustrating a configuration of an EL device, according to an embodiment of the technique of the present disclosure;

FIG. 2 is a circuit diagram illustrating an electrical configuration of a pixel of the EL device, together with a level of each node during a gradation operation period of the EL device, according to the embodiment;

FIG. 3 is a circuit diagram illustrating an electrical configuration of a pixel of the EL device, together with a level of each node during a block driving period of the EL device, according to the embodiment;

FIG. 4 is a timing diagram illustrating level transition of each node in a process of inspecting off characteristics, executed during the block driving period of the EL device, together with detection current transition when the drive transistor and the holding transistor have normal off characteristics, according to the embodiment;

FIG. 5 is a timing diagram illustrating level transition of each node in the process of inspecting off characteristics, executed during the block driving period of the EL device, together with detection current transition when an off current flows through the holding transistor, according to the embodiment;

FIG. 6 is a timing diagram illustrating transition level of each node in the process of inspecting off characteristics, executed during the block driving period of the EL device, together with detection current transition when an off current flows through the drive transistor, according to the embodiment;

FIG. 7 is a circuit diagram illustrating an electrical configuration of a first block selection circuit and a second block selection circuit, according to the embodiment;

FIG. 8 is a circuit diagram illustrating an electrical configuration of a data block setting circuit, according to the embodiment;

FIG. 9 is a circuit diagram illustrating an electrical configuration of a power supply block selection circuit, according to the embodiment;

FIG. 10 is a timing diagram illustrating level transition of each node in a process of inspecting off characteristics, together with drive current transition when a selection transistor operates normally, according to an EL device as a modification;

FIG. 11 is a timing diagram illustrating electrical potential transition of each node in the process of inspecting off characteristics, together with detection current transition when an off current flows through the selection transistor, according to the EL device as a modification;

FIG. 12 is a timing diagram illustrating electrical potential transition of each node in a process of inspecting on characteristics, together with detection current transition when a drive transistor operates normally, according to the EL device as a modification; and

FIG. 13 is a timing diagram illustrating electrical potential transition of each node in the process of inspecting on characteristics, together with detection current transition when an on current of the drive transistor is low, according to the EL device as a modification.

### DESCRIPTION OF THE EMBODIMENTS

The embodiments will now be described with reference to the accompanying drawings, wherein like reference numerals designate corresponding or identical elements throughout the various drawings.

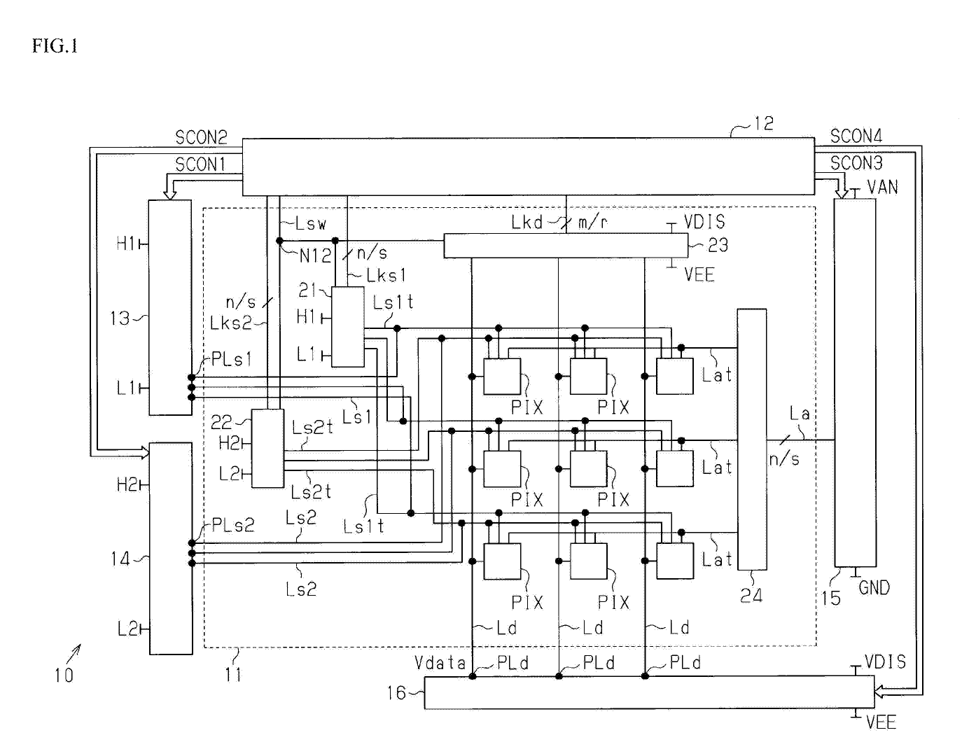

With reference to FIGS. 1 to 13, hereinafter are described a thin film transistor array device, an EL device, a sensor device, a method of driving a thin film transistor array device, a method of driving an EL device, and a method of driving a sensor device, according to an embodiment implementing the technique of the present disclosure. For the sake of convenience in describing a mode of connection between an EL panel and drivers, FIG. 1 shows a reduced number of pixels provided to the EL panel.

<EL Device>

As shown in FIG. 1, an EL device includes an EL panel 11, a system controller 12, a first selection driver 13, a second selection driver 14, a power supply driver 15, and a data driver 16.

A process of fabricating an EL device includes an inspection step in which the operation of the EL panel 11 is inspected. The inspection step of the EL panel 11 includes a block inspection step as a step of inspecting a plurality of pixels PIX provided to the EL panel 11, on a pixel-block basis, the pixel block corresponding to a set of pixels PIX, and a specific inspection step conducted per pixel PIX, the pixel PIX being finer than the pixel block.

The system controller 12 and the power supply driver 15 are connected to the EL panel 11 during a block driving period in which the block inspection step is performed. In contrast, the first selection driver 13, the second selection driver 14, and the data driver 16 are not connected to the EL panel 11 during the block driving period, but are connected to the EL panel 11 during an specific driving period in which the specific inspection step is performed.

The thin film transistor array device is composed of the system controller 12 and the power supply driver 15 which are connected to the EL panel 11 during the block driving period, and the EL panel 11 to which these components are connected. In this case, the EL panel 11 may be in a state before formation of EL elements OEL, or may be in a state after formation of the EL elements OEL.

<Configuration of Block>

In a display region of the EL panel 11, the EL panel 11 includes n first pixel selection lines Ls1t (n is an integer 4 or more) extending in a row direction, i.e. in one direction. In the n first pixel selection lines Ls1t, s first pixel selection lines Ls1t (s is an integer 2 or more, and is a divisor of n) having sequential row numbers constitute one first block. In each of a plurality of first blocks, the s first pixel selection lines Ls1t are correlated with a corresponding first block so that the row numbers of the first pixel selection lines Ls1t configuring the respective first blocks do not overlap among the mutually different first blocks. In the n first pixel selection lines Ls1t, first blocks of n/s rows are defined.

For example, the 1^{st}- to s^{th}-row first pixel selection lines Ls1t constitute a 1^{st}-row first block, and the (s+1)^{th}- to (2s)^{th}-row first pixel selection lines Ls1t constitute the 2^{nd}-row first block. Thus, the (n−s)^{th}- to n^{th}-row first pixel selection lines Ls1t constitute the (n/s)^{th}-row first block.

The EL panel 11 is provided with n second pixel selection lines Ls2t extending in the row direction. In the n second pixel selection lines Ls2t, s second pixel selection lines Ls2t having sequential row numbers constitute one second block. In each of a plurality of second blocks of the n second pixel selection lines Ls2t, the s second pixel selection lines Ls2t are correlated with a corresponding second block so that the row numbers of the second pixel selection lines Ls2t configuring the respective second blocks do not overlap among the second blocks. In the n second pixel selection lines Ls2t, the second blocks of n/s rows are defined.

For example, the 1^{st}- to s^{th}-row second pixel selection lines Ls2t constitute a 1^{st}-row second block, and the (s+1)^{th}- to (2s)^{th}-row second pixel selection lines Ls2t constitute the 2^{nd}-row second block. Thus, the (n−s)^{th}- to n^{th}-row second pixel selection lines Ls2t constitute the (n/s)^{th}-row second block.

The EL panel 11 includes n power supply lines Lat extending in the row direction. In the n power supply lines Lat, s power supply lines Lat having sequential row numbers constitute one power supply block. In each of a plurality of power supply blocks of the n power supply lines Lat, the s power supply lines Lat are correlated with a corresponding power supply block so that the row numbers of the power supply lines Lat configuring the respective power supply blocks do not overlap among the power supply blocks. In the n power supply lines Lat, power supply blocks of n/s rows are defined.

For example, the 1^{st}- to s^{th}-row power supply lines Lat constitute a 1^{st}-row power supply block, and the (s+1)^{th}- to (2s)^{th}-row power supply lines Lat constitute the 2^{nd}-row power supply block. Thus, the (n−s)^{th}- to n^{th}-row power supply lines Lat constitute the (n/s)^{th}-row power supply block.

In the display region of the EL panel 11, the EL panel 11 includes m data lines Ld (m is an integer 4 or more) extending in a column direction perpendicular to the row direction. In the m data lines Ld, r data lines Ld (r is an integer 2 or more and is a divisor of m) having sequential column numbers constitute one data block. In each of a plurality of data blocks, the r data lines Ld are correlated with a corresponding data block so that the column numbers of the data lines Ld configuring the respective data blocks do not overlap among the data blocks. In the m data lines Ld, the data blocks of m/r columns are defined.

For example, the 1^{st}- to r^{th}-column data lines Ld constitute a 1^{st}-column data block, and the (r+1)^{th}- to (2r)^{th}-column data lines Ld constitute a 2^{nd}-column data block. Thus, the (m−r)^{th}- to m^{th}-column data lines Ld constitute the (m/r)^{th}-column data block.

In the EL panel 11, the pixels PIX are located near respective areas where the n first pixel selection lines Ls1t, the n second pixel selection lines Ls2t, and the m data lines Ld intersect in a three dimensional manner. The plurality of pixels PIX are located in an n rows×m columns matrix pattern. In the plurality of pixels PIX in a matrix pattern, pixels PIX of each selection row are connected to one first pixel selection line Ls1t, and also pixels PIX of each selection row are connected to one second pixel selection line Ls2t. In the plurality of pixels PIX in a matrix pattern, pixels PIX of each selection row are connected to one power supply line Lat, and also pixels PIX of each column are connected to one data line Ld.

One row block is made up of a plurality of first selection rows, as an example of the selection rows included in one first block. The plurality of first selection rows are each made up of pixel circuits DC, as an example of the element circuits included in the pixels PIX of the m columns, and one first pixel selection line Ls1t to which one row×m columns of pixels PIX are parallelly connected.

One column block is made up of a plurality of output columns included in one data block. The plurality of output columns are each made up of pixel circuits DC included in the n rows of pixels PIX and one data line Ld to which n rows×1 column of pixels PIX are parallelly connected.

<Configuration of Block Circuits>

The EL panel 11 includes a first block selection circuit 21 and a second block selection circuit 22, as an example of the row block selection circuit, a data block setting circuit 23, as an example of the column block setting circuit, and a power supply block selection circuit 24.

The n first pixel selection lines Ls1t are parallelly connected to the first block selection circuit 21 in common use. n/s first block selection lines Lks1, as an example of the row block selection line, are parallelly connected between the first block selection circuit 21 and the system controller 12. The first block selection circuit 21 correlates each of the plurality of first blocks in the n first pixel selection lines Ls1t with a corresponding first block selection line Lks1.

The first selection driver 13 includes n rows of first connection terminals PLs1, and each of the n rows of first connection terminals PLs1 is electrically connected to a corresponding first specific pixel selection line Ls1. Each of the n first specific pixel selection lines Ls1 is electrically connected to a corresponding first pixel selection line Ls1t. Further, the first block selection circuit 21 and the first selection driver 13 are connected parallel to the n first pixel selection lines Ls1t.

The n second pixel selection lines Ls2t are parallelly connected to the second block selection circuit 22 in common use. n/s second block selection lines Lks2 are parallelly connected between the second block selection circuit 22 and the system controller 12. The second block selection circuit 22 correlates each of the plurality of second blocks in the n second pixel selection lines Ls2t with a corresponding second block selection line Lks2.

The second selection driver 14 includes n rows of second connection terminals PLs2, and each of the n rows of second connection terminals PLs2 is electrically connected to a corresponding second specific pixel selection line Ls2. Each of the n second specific pixel selection lines Ls2 is electrically connected to a corresponding second pixel selection line Ls2t. Further, the second block selection circuit 22 and the second selection driver 14 are connected parallel to the n second pixel selection lines Ls2t.

The n power supply lines Lat are parallelly connected to the power supply block selection circuit 24 in common use. n/s power supply block selection lines La are parallelly connected between the power supply block selection circuit 24 and the power supply driver 15. The power supply block selection circuit 24 correlates each of the plurality of power supply blocks in the n power supply lines Lat with a corresponding power supply block selection line La.

The m data lines Ld are parallelly connected to the data block setting circuit 23 in common use. m/r data block setting lines Lkd, as an example of the column block selection line, are parallelly connected between the data block setting circuit 23 and the system controller 12. The data block setting circuit 23 correlates each of the plurality of data blocks in the m data lines Ld with a corresponding data block setting line Lkd.

The data driver 16 includes terminals PLd for the m columns of data lines. Each of the terminals PLd is electrically connected to a corresponding data line Ld. Further, the m data lines Ld are parallelly connected between the data block setting circuit 23 and the data driver 16.

A logic power supply, which is an external circuit of the EL panel 11, supplies a logic voltage of a first selection level H1 or a first non-selection level L1 separately to the first block selection circuit 21 and the first selection driver 13. During the block driving period of the EL panel 11, the first block selection circuit 21 applies either the first selection level H1 or the first non-selection level L1 to the n first pixel selection lines Ls1t. During a gradation driving period of the EL panel 11, the first selection driver 13 applies either the first selection level H1 or the first non-selection level L1 to the n first specific pixel selection lines Ls1.

The logic power supply supplies logic voltages of a second selection level H2 and a second non-selection level L2 separately to the second block selection circuit 22 and the second selection driver 14. During the block driving period of the EL panel 11, the second block selection circuit 22 applies either the second selection level H2 or the second non-selection level L2 to the n second pixel selection lines Ls2t. During the gradation driving period of the EL panel 11, the second selection driver 14 applies either the second selection level H2 or the second non-selection level L2 to the n second specific pixel selection lines Ls2.

The first selection level H1 only needs to be a level at which an on current is passed to the holding transistor provided to the pixel PIX, and the second selection level H2 only needs to be a level at which an on current is passed to the selection transistor provided to the pixel PIX. These levels may be equal to or different from each other. The first non-selection level L1 only needs to be a level at which current is not passed to the holding transistor provided to the pixel PIX, and the second non-selection level L2 only needs to be a level at which current is not passed to the selection transistor provided to the pixel PIX. These levels may be equal to or different from each other.

An analog power supply, which is an external circuit of the EL panel 11, supplies analog voltages of a reference level VEE and a display level VDIS separately to the data block setting circuit 23 and the data driver 16. During the block driving period of the EL panel 11, the data block setting circuit 23 applies levels based on the reference level VEE and the display level VDIS to the m data lines Ld. During the gradation driving period of the EL panel 11, the data driver 16 generates a gradation level Vdata based on gradation data, on the basis of the display level VDIS to apply the gradation level Vdata to the m data lines Ld.

The analog power supply supplies analog voltages of a ground level GND and an anode level VAN separately to the power supply driver 15. During the block driving period and the gradation driving period of the EL panel 11, the power supply driver 15 generates a writing level Vccw equal to the reference level VEE to apply the writing level Vccw to the n power supply block selection lines La. Further, during the block driving period and the gradation driving period of the EL panel 11, the power supply driver 15 generates a light emission level Vcss higher than the writing level Vccw on the basis of an anode level VAN to apply the light emission level Vcss to the n power supply block selection lines La.

<Block Selection Line and Block Gate Line>

The first block selection circuit 21 is electrically connected to one block gate line Lsw through a node N12 provided to the EL panel 11. The second block selection circuit 22 is also electrically connected, similarly to the first block selection circuit 21, to one block gate line Lsw through the node N12 provided to the EL panel 11. The block gate line Lsw is a signal line to establish the block driving period in the EL panel 11 and electrically connected to the system controller 12. The system controller 12 switches the level, or, the electrical potential, of the block gate line Lsw from a permission level to a prohibition level, or vice versa.

The system controller 12 outputs a permission level to the block gate line Lsw, during the block driving period of an EL device 10. Outside the block driving period of the EL device 10, the system controller 12 outputs a prohibition level to the block gate line Lsw. When a permission level is outputted to the block gate line Lsw, the first block selection circuit 21 selects one first block from the n first pixel selection lines Ls1t according to a signal outputted to the first block selection lines Lks1 by the system controller 12. When a permission level is outputted to the block gate line Lsw, the second is block selection circuit 22 also selects one second block from the n second pixel selection lines Ls2t according to a signal outputted to the second block selection lines Lks2 by the system controller 12. In contrast, when a prohibition level is outputted to the block gate line Lsw, the first block selection circuit 21 stops selecting first blocks and the second block selection circuit 22 also stops selecting second blocks.

The first block selection circuit 21 correlates each of the n/s first block selection lines Lks1 with a corresponding first block. For example, the 1^{st}-row first block selection line Lks1 is correlated with the 1^{st}-row first block, and the 2^{nd}-row first block selection line Lks1 is correlated with the 2^{nd}-row first block. Thus, the (n/s)^{th}-row first block selection line Lks1 is correlated with the (n/s)^{th}-row first block.

The system controller 12 has a sequence function. During the block driving period of the EL panel 11, using the sequence function, the system controller 12 selects the n/s first block selection lines Lks1, one by one, as an inspection target in order of row number. Also, during the block driving period of the EL panel 11, the system controller 12 selects, as non-inspection targets, the first block selection lines Lks1 which have not been selected as inspection targets, from among the n/s first block selection lines Lks1.

When a first block selection line Lks1 is selected as an inspection target, the first block selection circuit 21 applies a level appropriate to the inspection target simultaneously to the s first pixel selection lines Ls1t corresponding to the first block selection line Lks1. In contrast, when a first block selection line Lks1 is selected as a non-inspection target, the first block selection circuit 21 applies the first non-selection level L1 simultaneously to the s first pixel selection lines Ls1t corresponding to the first block selection line Lks1.

For example, when the 1^{st}-row first block selection line Lks1 is selected as an inspection target, the first block selection circuit 21 applies the first selection level H1 simultaneously across the 1^{st}- to s^{th}-row first pixel selection lines Ls1t. Further, for example, when the 1^{st}-row first block selection line Lks1 is selected as the other inspection target, the first block selection circuit 21 applies the first selection level H1 simultaneously across the 1^{st}- to s^{th}-row first pixel selection lines Ls1t for a predetermined period, and then applies the first non-selection level L1 simultaneously. In contrast, with the 1^{st} to n/s^{th}-row first block selection lines Lks1 being selected as non-inspection targets, the first block selection circuit 21 applies the first non-selection level L1 simultaneously across the (s+1)^{th}- to n^{th}-row first pixel selection lines Ls1t.

The second block selection circuit 22 is electrically connected to the system controller 12 via the n/s second block selection lines Lks2. The second block selection circuit 22 correlates each of the n/s second block selection lines Lks2 with a corresponding row block. For example, the 1^{st}-row second block selection line Lks2 is correlated with the 1^{st}-row row block, and the 2^{nd}-row second block selection line Lks2 is correlated with the 2^{nd}-row row block. Thus, the (n/s)^{th}-row second block selection line Lks2 is correlated with the (n/s)^{th}-row row block.

During the block driving period of the EL panel 11, using the sequence function, the system controller 12 selects the n/s second block selection lines Lks2, one by one, as an inspection target in order of row number. During the block driving period of the EL panel 11, the system controller 12 selects the second block selection lines Lks2, as non-inspection targets, which have not been selected as inspection targets, from among the n/s second block selection lines Lks2.

Then, when a second block selection line Lks2 is selected as an inspection target, the second block selection circuit 22 applies a level appropriate to the inspection target simultaneously to the s second pixel selection lines Ls2t corresponding to the second block selection line Lks2. In contrast, when the second block selection line Lks2 is selected as a non-inspection target, the second block selection circuit 22 applies the second non-selection level L2 simultaneously to the s second pixel selection lines Ls2t corresponding to the second block selection line Lks2.

For example, when the 1^{st}-row second block selection line Lks2 is selected as an inspection target, the second block selection circuit 22 applies the second selection level H2 simultaneously across the 1st- to s^{th}-row second pixel selection lines Ls2t. Further, for example, when the 1^{st}-row second block selection line Lks2 is selected as the other inspection target, the second block selection circuit 22 applies the second selection level H2 simultaneously across the 1^{st}- to s^{th}-row second pixel selection lines Ls2t for a predetermined period, and then applies the second non-selection level L2 simultaneously. In contrast, with the 2^{nd}- to (n/s)^{th}-row second block selection lines Lks2 being selected as non-inspection targets, the second block selection circuit 22 applies the second non-selection level L2 simultaneously across the (s+1)^{th}- to n^{th}-row second pixel selection lines Ls2t.

The power supply block selection circuit 24 is electrically connected to the power supply driver 15 via the n/s power supply block selection lines La. The power supply block selection circuit 24 correlates each of the n/s power supply block selection lines La with a corresponding power supply block. For example, the 1^{st}-row power supply block selection line La is correlated with the 1^{st}-row power supply block, and the 2^{nd}-row power supply block selection line La is correlated with the 2^{nd}-row power supply block. Thus, the (n/s)^{th}-row power supply block selection line La is correlated with the (n/s)^{th}-row power supply blocks.

During the block driving period of the EL panel 11, using the sequence function, the system controller 12 selects the n/s power supply block selection lines La, one by one, as an inspection target in order of row number through driving of the power supply driver 15. Also, during the block driving period of the EL panel 11, the system controller 12 selects, as non-inspection targets, power supply block selection lines La which have not been selected as inspection targets, from among the n/s power supply block selection lines La, through driving of the power supply driver 15.

Then, when a power supply block selection line La is selected as an inspection target, the power supply block selection circuit 24 applies a level appropriate to the inspection target simultaneously to the s power supply lines Lat corresponding to the power supply block selection line La. In contrast, when a power supply block selection line La is selected as a non-inspection target, the power supply block selection circuit 24 applies the reference level VEE simultaneously to the s power supply lines Lat corresponding to the power supply block selection line La.

For example, when the 1^{st}-row power supply block selection line La is selected as an inspection target, the writing level Vccw is applied simultaneously across the 1^{st}- to s^{th}-row power supply lines Lat. Further, for example, when the 1^{st}-row power supply block selection line La is selected as the other inspection target, the writing level Vccw is applied simultaneously across the 1^{st}- to s^{th}-row power supply lines Lat for a predetermined period, and then the light emission level Vcss is applied simultaneously. In contrast, with the 2^{nd}- to (n/s)^{th}-row power supply block selection lines La being selected as non-inspection targets, the reference level VEE is applied simultaneously across the (s+1)^{th}- to n^{th}-row power supply lines Lat.

Of the n/s first block selection lines Lks1, the n/s second block selection lines Lks2, and the n/s power supply block selection lines La, the sequence function of the system controller 12 selects a selection line in such a way that the row numbers of the inspection targets coincide with each other. Then, the sequence function of the system controller 12 synchronizes applications of levels that are appropriate to the respective inspection targets, in the first pixel selection lines Ls1t, the second pixel selection lines Ls2t, and the power supply lines Lat, on a row-block basis.

The data block setting circuit 23 is electrically connected to one block gate line Lsw through the node N12 provided to the EL panel 11, in a manner similar to the first and second block selection circuits 21 and 22. That is, the first and second block selection circuits 21 and 22 and the data block setting circuit 23 are parallelly connected to one block gate line Lsw.

When a permission level is outputted to the block gate line Lsw, the data block setting circuit 23 selects one column block from the m data lines Ld according to a signal outputted by the system controller 12. When a prohibition level is outputted to the block gate line Lsw, the data block setting circuit 23 stops selecting column blocks.

The data block setting circuit 23 is electrically connected to the system controller 12 via the m/r data block setting lines Lkd. The data block setting circuit 23 correlates each of the m/r data block setting lines Lkd with a corresponding column block. For example, the 1^{st}-column data block setting line Lkd is correlated with the 1^{st}-column block, and the 2^{nd}-column data block setting line Lkd is correlated with the 2^{nd}-column block. Thus, the (m/r)^{th}-column data block setting line Lkd is correlated with the (m/r)^{th}-column block.

The system controller 12 includes a current measurement unit 23a to measure a current, as a detection current I, flowing through each of the m/r data block setting lines Lkd. The system controller 12 includes a storage unit to store measurements of detection current, being correlated with column numbers of the data block setting line Lkd.

During the block driving period of the EL panel 11, the sequence function of the system controller 12 simultaneously selects the m/r data block setting lines Lkd as inspection targets to cause the current measurement unit 23a to measure the current flowing through the data block setting lines Lkd. Then, the data block setting circuit 23 applies levels appropriate to the respective inspection targets simultaneously to the m data lines Ld.

For example, when the m/r data block setting lines Lkd are selected as inspection targets, the data block setting circuit 23 applies a gradation level VdatB equivalent to displaying black simultaneously to the m data lines Ld. Further, for example, when the m/r data block setting lines Lkd are selected as other inspection targets, the data block setting circuit 23 applies a gradation level VdatW equivalent to displaying white simultaneously to the m data lines Ld. Further, for example, when the m/r data block setting lines Lkd are selected as other inspection targets, the data block setting circuit 23 applies the gradation level VdatB equivalent to displaying black simultaneously to the m data lines Ld for a predetermined period, and then applies the gradation level VdatW equivalent to displaying white simultaneously. It should be noted that the gradation level VdatB equivalent to displaying black is ensured to be equal to the writing level Vccw. The gradation level VdatW equivalent to displaying white, which is lower than the writing level Vccw, is determined such that the difference between the gradation level VdatW equivalent to displaying white and the writing level Vccw becomes sufficiently greater than a threshold voltage of a drive transistor T1.

During the block driving period of the EL panel 11, the sequence function of the system controller 12 selects the m/r data block setting lines Lkd as inspection targets, every time a new first block selection line Lks1 is selected as an inspection target to thereby measure the current flowing through the data block setting lines Lkd. Then, the sequence function of the system controller 12 synchronizes selection of the row blocks to be inspected with measurement of the detection current I on a row-block basis.

Thus, the system controller 12 obtains the detection current I of the 1^{st}- to (m/r)^{th}-column column blocks, for the 1^{St}- to (n/s)^{th}-row row blocks, on a row-block basis, in order of row number. In this case, in the areas where one row block and one column block intersect three dimensionally, s rows×r columns of pixels PIX are located. Therefore, the detection current I for each data block setting line Lkd measured by the system controller 12 is a representative value of the inspection results of a pixel block configured by the s rows×r columns of pixels PIX. Thus, the system controller 12 stores the data of (n/s) rows×(rink) columns representative values as inspection results of the EL panel 11.

<Configuration of Various Drivers>

During the gradation driving period of the EL device 10, the system controller 12 generates a first selection control signal SCON1 to control driving of the first selection driver 13 on the basis of an image signal inputted from outside, and inputs the first selection control signal SCON1 to the first selection driver 13.

The first selection driver 13 includes a shift register to sequentially shift the first selection control signals SCON1 outputted from the system controller 12 as start pulses. The shift register outputs shift signals corresponding to the 1^{st}- to n^{th}-row pixel selection lines Ls1t in order of row number.

The first selection driver 13 includes an output buffer to generate a first selection signal at the first selection level H1 which has been converted from the level of a shift signal. The output buffer outputs the first selection signal, which is set to the first selection level H1, to the first pixel selection line Ls1t of the row corresponding to the shift signal, and outputs a first selection signal, which is set to the first non-selection level L1, to the first pixel selection lines Ls1t of the rows not corresponding to the shift signal. Thus, the first selection driver 13 outputs a first selection signal, which is set to the first selection level H1, to each of the n first pixel selection lines Ls1t in order of row number to select the n rows×m columns of pixels PIX on a selection-row basis.

During the driving period of the EL device 10, the system controller 12 generates a second selection control signal SCON2 to control driving of the second selection driver 14 on the basis of an image signal inputted from outside, and inputs the second selection control signal SCON2 to the second selection driver 14.

The second selection driver 14 includes a shift register to sequentially shift the second selection control signals SCON2 outputted from the system controller 12 as start pulses. The shift register outputs shift signals corresponding to the to n^{th}-row second pixel selection lines Ls2t in order of row number.

The second selection driver 14 includes an output buffer to generate a second selection signal at the second selection level H2 which has been converted from the level of the shift signal. The output buffer outputs the second selection signal, which is set to the second selection level H2, to the second pixel selection line Ls2t of the row corresponding to the shift signal, and outputs a second selection signal set to the second non-selection level L2 to the second pixel selection lines Ls2t of the rows not corresponding to the shift signal. Thus, the second selection driver 14 outputs the second selection signal set to the second selection level H2 to each of the n second pixel selection lines Ls2t in order of row number to select the n rows×m columns of pixels PIX on a selection-row basis.

During the gradation driving period of the EL device 10, the system controller 12 extracts gradation components included in the image signal, and converts the gradation components into input data as digital values, on the basis of image signals inputted from outside. The system controller 12 outputs the selection-row basis input data of the EL panel 11 to the data driver 16 in order of column number. The system controller 12 generates a data control signal SCON4 to control driving of the data driver 16 and inputs the data control signal SCON4 to the data driver 16.

The data driver 16 holds the pixel-PIX basis input data outputted from the system controller 12 in order of column number on a selection-row basis. The data driver 16 generates the gradation level Vdata, which is an electrical potential for each data line Ld, on the basis of the input data corresponding to one selection row that has been held, and applies the gradation level Vdata simultaneously to the individual m data lines Ld. The system controller 12 causes the data driver 16 to drive the pixels PIX on the basis of such gradation level Vdata during the gradation driving period.

During the gradation driving period of the EL device 10, the system controller 12 generates a power supply control signal SCON3 on the basis of an image signal inputted from outside to control driving of the power supply driver 15, and inputs the power supply control signal SCON3 into the power supply driver 15.

The power supply driver 15 includes a timing generator which is driven based on the power supply control signal SCON3, and an output buffer. The timing generator generates timing signals corresponding to the respective n power supply block selection lines La. The output buffer converts each timing signal generated by the timing generator into a predetermined level to output the converted signal as a power supply signal to a corresponding n/s power supply block selection line La.

For example, to cause an i^{th}-row pixel PIX (i is an integer from 1 to n) to execute writing operation, the system controller 12 applies the writing level Vccw to the power supply block selection line La corresponding to the i^{th}-row power supply line Lat, through driving of the power supply driver 15. In addition, to cause the i^{th}-row pixel PIX to emit light, the system controller 12 applies the light emission level Vcss to the power supply block selection line La corresponding to the i^{th}-row power supply line Lat, through driving of the power supply driver 15.

<Configuration of Pixel>

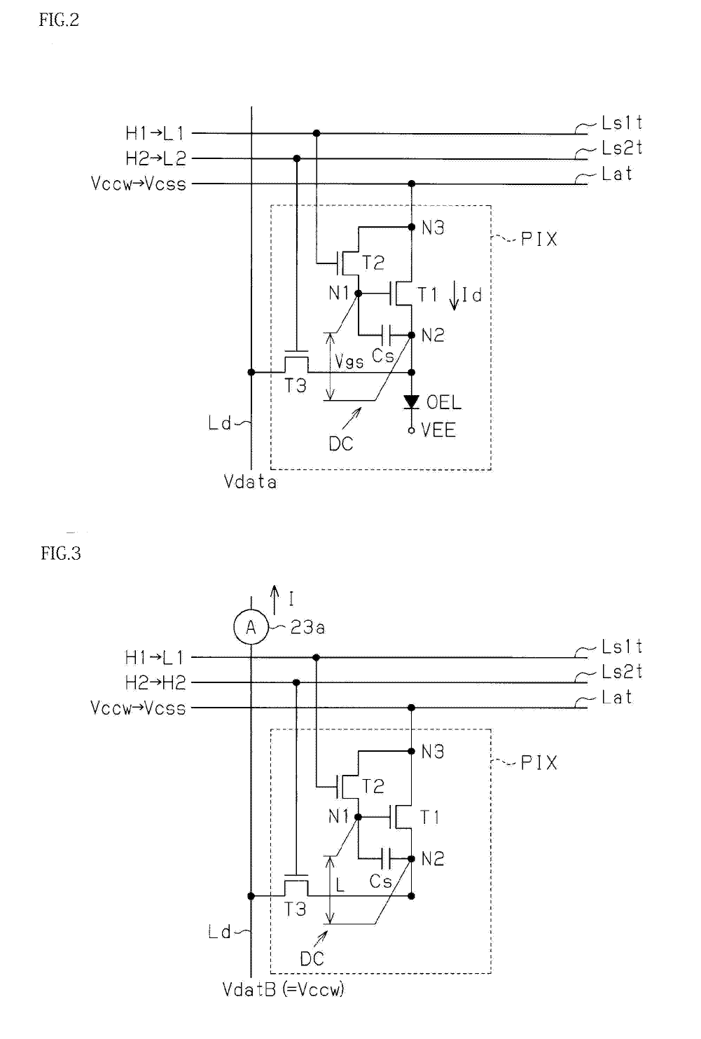

Referring now to FIG. 2, the configuration of each pixel PIX provided to the EL panel 11 will be described.

As shown in FIG. 2, each of the plurality of pixels PIX includes the EL element OEL as a current driving element, and the pixel circuit DC to drive the EL element OEL. The pixel circuit DC includes the drive transistor T1, a holding transistor T2, a selection transistor T3, and a holding capacitor Cs. In the present embodiment, the thin film transistor array device is composed of the components other than the EL elements OEL among the components of the EL panel 11.

The drive transistor T1 is an n-channel transistor having a gate electrically connected to the source of the holding transistor T2 through a node N1. The source of the drive transistor T1 is electrically connected to the anode of the EL element OEL through a node N2, and the drain of the drive transistor T1 is electrically connected to the power supply line Lat through a node N3. The drive transistor T1 passes a drive current corresponding to a gate-source voltage to a saturation region.

The anode of the EL element OEL is electrically connected to the source of the drive transistor T1 through the node N2. A cathode voltage whose level is made equal to the writing level Vccw is applied to the cathode of the EL element OEL.

A first electrode, which is one of two electrodes of the holding capacitor Cs, is electrically connected to the gate of the drive transistor T1 through the node N1, and a second electrode, which is the other electrode of the holding capacitor Cs, is electrically connected to the source of the drive transistor T1. The holding capacitor Cs may be a parasitic capacitor formed between the gate and the source of the drive transistor T1, or may be a capacitor element separately provided between the gate and the source of the drive transistor T1, or may be a combination of these configurations. The holding capacitor Cs holds the gate-source voltage of the drive transistor T1.

The holding transistor T2 is an n-channel transistor having a gate electrically connected to the first pixel selection line Ls1t. The drain of the holding transistor T2 is electrically connected to the drain of the drive transistor T1 through the node N2, and the source of the holding transistor T2 is electrically connected to the gate of the drive transistor T1 through the node N1.

The holding transistor T2 selects whether to diode-connect the drive transistor T1 thereto on the basis of the voltage level applied to the first pixel selection line Ls1t. Also, when establishing a diode-connection with the drive transistor T1, the holding transistor T2 causes the holding capacitor Cs to hold a voltage corresponding to the difference between the level of the power supply line Lat and the level of the data line Ld.

The selection transistor T3 is an n-channel transistor having a gate electrically connected to the second pixel selection line Ls2t. The source of the selection transistor T3 is electrically connected to the data line Ld, and the drain of the selection transistor T3 is electrically connected to the source of the drive transistor T1 through the node N2.

The selection transistor T3 select whether to electrically connect the source of the drive transistor T1 to the data line Ld on the basis of the voltage level applied to the second pixel selection line Ls2t. The selection transistor T3 causes the holding capacitor Cs to hold a voltage corresponding to the difference between the level of the power supply line Lat and the level of the data line Ld, cooperating with the drive transistor T1 and the holding transistor T2.

<Level of Voltage Applied>

Taking one pixel PIX as an example, the following description addresses the voltage level, as an electrical potential, applied by the sequence function of the system controller 12, to each of the first pixel selection lines Ls1t, the second pixel selection lines Ls2t, the power supply lines Lat, and the data lines Ld.

During the gradation driving period, the system controller 12 drives the first selection driver 13, the second selection driver 14, the power supply driver 15, and the data driver 16 to cause them, in turn, to execute the writing operation and the light emission operation.

During the block driving period, the system controller 12 drives the first block selection circuit 21, the second block selection circuit 22, the data block setting circuit 23, and the power supply block selection circuit 24 to cause them, in turn, to execute block resetting operation and detection operation.

In the process of fabricating an EL device, the block driving period may be established in a step of inspecting a thin film transistor array device before formation of an EL element OEL, or may be established in a step of inspecting a thin film transistor array device after formation of an EL element OEL. Of these opportunities, the present embodiment shows an example in which the block driving period is established in the step of inspecting a thin film transistor array device before formation of an EL element OEL. As an example of inspection performed during the block driving period, off characteristics inspection of the drive transistor T1 and the holding transistor T2 is shown

As shown in FIG. 2, in the writing operation, the first selection driver 13 firstly applies the first selection level H1 to the first pixel selection line Ls1t, and causes the holding transistor T2 to transition to an on state. The second selection driver 14 applies the second selection level H2 to the second pixel selection line Ls2t, and causes the selection transistor T3 to transition to an on state. The power supply driver 15 applies the writing level Vccw to the power supply line Lat. Then, the data driver 16 applies the gradation level Vdata to the data line Ld. Thus, a voltage corresponding to the difference between the writing level Vccw and the gradation level Vdata is written into the holding capacitor Cs, as a gate-source voltage Vgs of the drive transistor T1.

The system controller 12 drives the first selection driver 13, the second selection driver 14, the power supply driver 15, and the data driver 16 to cause the 1^{st}- to n^{th}-row pixels PIX to repeat such writing operation to the holding capacitor Cs, row by row, in order of row number.

In the light emission operation, the first selection driver 13 applies the first non-selection level L1 to the first pixel selection line Ls1t, and causes the holding transistor T2 to transition to an off state. The second selection driver 14 applies the second non-selection level L2 to the second pixel selection line Ls2t, and causes the selection transistor T3 to transition to an off state. The power supply driver 15 applies the light emission level Vcss to the power supply line Lat. In response to such level changes, the drive transistor T1 passes a drive current Id corresponding to the voltage written into the holding capacitor Cs to the EL element OEL, on the basis of the difference between the light emission level Vcss and the reference level VEE to cause the EL element OEL to emit light. Then, the first selection driver 13, the second selection driver 14, the power supply driver 15, and the data driver 16 cause the m columns of pixels PIX, for 1^{st} to n^{th} rows, to execute such light emission operation of the EL elements OEL, on a selection-row basis, in order of finishing the writing operation.

During the block driving period, the first selection driver 13, the second selection driver 14, and the data driver 16 are not connected to the EL panel 11, and the n rows of first connection terminals PLs1, the n rows of second connection terminals PLs2, and the data line terminals PLd for m columns are permitted to be floating terminals.

As shown in FIG. 3, in the black resetting operation, the first block selection circuit 21 applies the first selection level H1 to the first pixel selection line Ls1t, and causes the holding transistor T2 to transition to an on state. The second block selection circuit 22 applies the second selection level H2 to the second pixel selection line Ls2t, and causes the selection transistor T3 to transition to an on state. The power supply driver 15 applies the writing level Vccw to the power supply line Lat. The data block setting circuit 23 applies the gradation level VdatB equivalent to displaying black to the data line Ld. In this case, the holding transistor T2 and the selection transistor T3 are in an on state, while the gradation level VdatB equivalent to displaying black is equal to the writing level Vccw. Therefore, while the drive transistor T1 is in a diode-connection, the drive current Id does not flow between the power supply line Lat and the data line Ld. As a result, the holding transistor T2 and the selection transistor T3 write a voltage at a low level L, which is equivalent to the difference between the gradation level VdatB and the writing level Vccw, into the holding capacitor Cs.

In the detection operation, the first block selection circuit 21 applies the first non-selection level L1 to the first pixel selection line Ls1t, and causes the holding transistor T2 to transition to an off state. The second block selection circuit 22 continues applying the second selection level H2 to the second pixel selection line Ls2t to maintain the on state of the selection transistor T3. The power supply driver 15 applies the light emission level Vcss, which is at a high level, to the power supply line Lat. Then, the system controller 12 causes the current measurement unit 23a to measure the current flowing through each of the m/r data block setting lines Lkd as the detection current I.

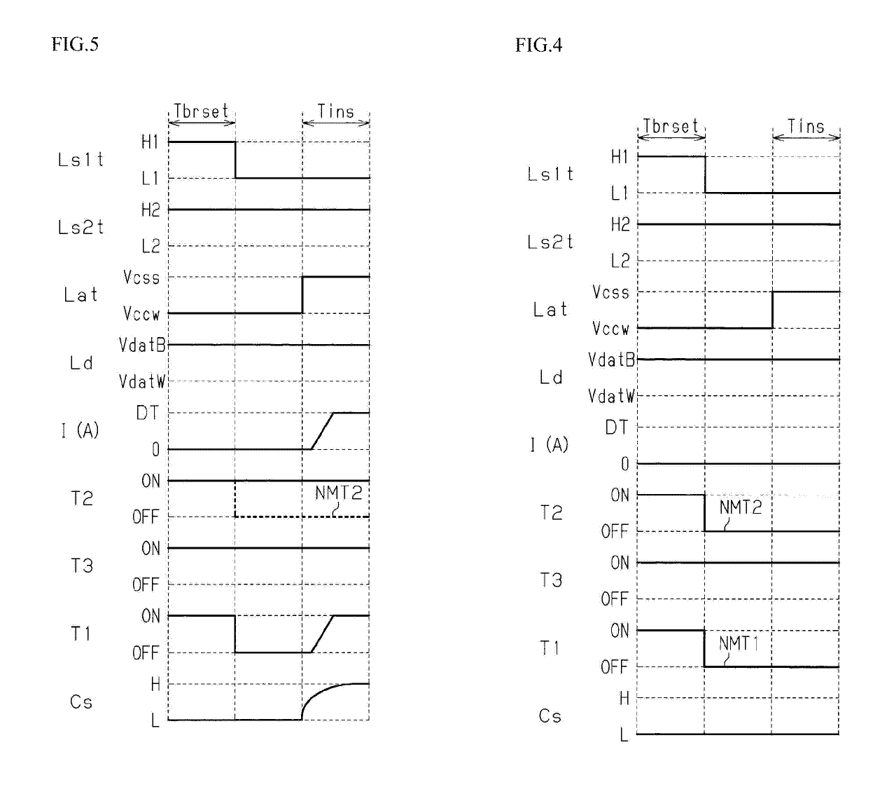

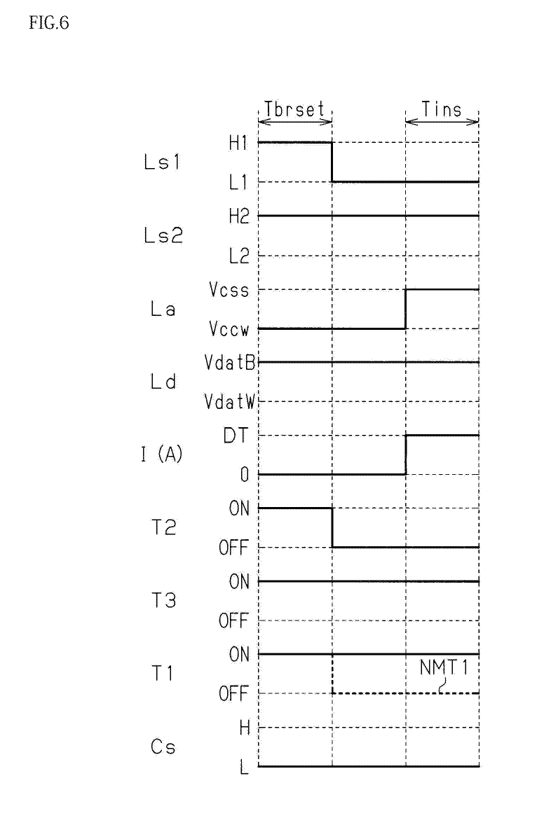

FIGS. 4 to 6 are timing diagrams illustrating examples of transition of the detection current I in the black resetting operation and the detection operation. As can be seen, the off characteristics of the drive transistor T1 and those of the holding transistor are different between the diagrams. FIG. 4 is a timing diagram illustrating transition of the detection current I when the drive transistor T1 and the holding transistor T2 have normal off characteristics. FIG. 5 is a timing diagram illustrating transition of the detection current I when an off current flows through the holding transistor T2. FIG. 6 is a timing diagram illustrating transition of the detection current I when an off current flows through the drive transistor T1.

As shown in FIG. 4, during a black resetting period Tbrset in which the black reset operation is executed, due to the application of the first and second selection levels H1 and H2, the holding transistor T2 and the selection transistor T3 are permitted to transition to an on state. With the transition of the holding transistor T2 to an on state, the drive transistor T1 is permitted to transition to an on state. Due to the application of the writing level Vccw and the gradation level VdatB equivalent to displaying black, the voltage at the low level L, which is equivalent to the difference between the gradation level VdatB and the writing level Vccw, is written into the holding capacitor Cs.

During a detection period Tins in which the detection operation is executed, due to the application of the first and second selection levels H1 and H2, the holding transistor T2 is permitted to transition to an off state (solid line NMT2), while the selection transistor T3 maintains an on state. In this case, the voltage of the holding capacitor Cs written by the black resetting operation is at the low level L. Therefore, with the transition of the holding transistor T2 to an off state, the drive transistor T1 is also permitted to transition to an off state (solid line NMT1). Then, due to the application of the light emission level Vcss and the gradation level VdatB equivalent to displaying black, a forward bias equivalent to the difference between the light emission level Vcss and the gradation level VdatB, which is equivalent to displaying black, is applied to a serial connection circuit made up of the drive transistor T1 in an off state and the selection transistor T3 in an on state.

When the off characteristics of the drive transistor T1 and those of the holding transistor T2 are normal, the voltage that has been written into the holding capacitor Cs is maintained at the low level L and the detection current I detected by the current measurement unit 23a indicates approximately 0.

In contrast, there may be a situation, as shown in FIG. 5, where a non-negligible off current flows through the holding transistor T2, such as when many defects are included in a gate film of the holding transistor T2. In this situation, if the light emission level Vcss is applied during the detection period Tins, the holding transistor T2 continues maintaining a conduction state as in an on state, as indicated by the solid line. Then, conforming to the flow of the off current through the holding transistor T2, a voltage at a high level H equivalent to the difference between the gradation level VdatB, which is equivalent to displaying black, and the light emission level Vcss, is written into the holding capacitor Cs. In this case, when the voltage written into the holding capacitor Cs exceeds a threshold voltage of the drive transistor T1, the drive transistor T1 is permitted to transition from an off state to an on state of being driven in a saturated region. As a result, when a non-negligible off current flows through the holding transistor T2, an off current DT of the holding transistor T2 gradually rises, as the detection current I, on or after the point of applying the light emission level Vcss.

As shown in FIG. 6, there may be a situation where a non-negligible off current flows through the drive transistor T1, such as when the source-drain of the drive transistor T1 is short-circuiting. In this situation, if the light emission level Vcss is applied during the detection period Tins, the drive transistor T1 continues maintaining a conduction state as in an on state, as indicated by the solid line. As a result, when a non-negligible off current flows through the drive transistor T1, the off current DT of the drive transistor T1 immediately rises, as the detection current I, on or after the point of applying the light emission level Vcss.

The system controller 12 measures the current flowing through each of the m/r data block setting lines Lkd as the detection current I, and stores the measurements of the detection current I, being correlated to the column numbers of the data block setting lines Lkd. In this case, since mutually different r data lines Ld are parallelly connected to one data block setting line Lkd, the detection current I flowing through the data block setting line Lkd indicates a sum of the detection currents I flowing through the pixels PIX of r columns.

Therefore, when the measurements of the detection current I flowing through the data block setting lines Lkd are ensured to be correlated to the column numbers of the data block setting lines Lkd, whether the off characteristics of the drive transistor T1 are normal can be confirmed at the same time, for all the pixels PIX included in an area where one column block intersects one row block. Similarly, normality, i.e. whether the off characteristics of the holding transistor T2 are normal, can also be confirmed at the same time, for all the pixels PIX included in an area where one column block intersects one row block.

<Detailed Configuration of Block Circuit>

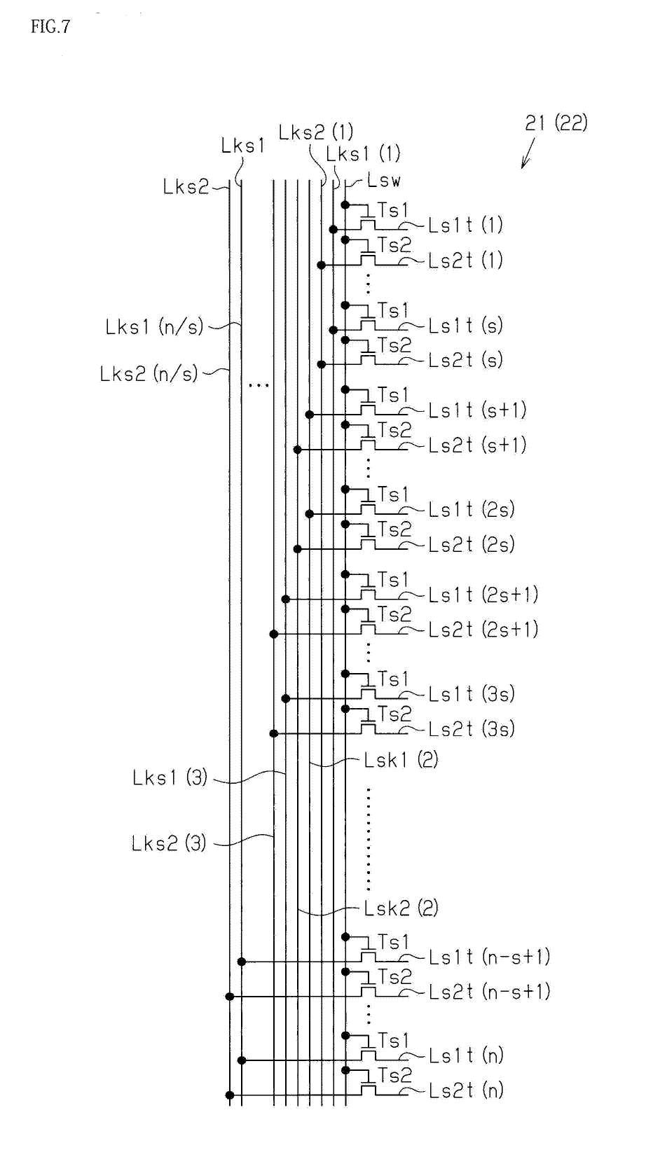

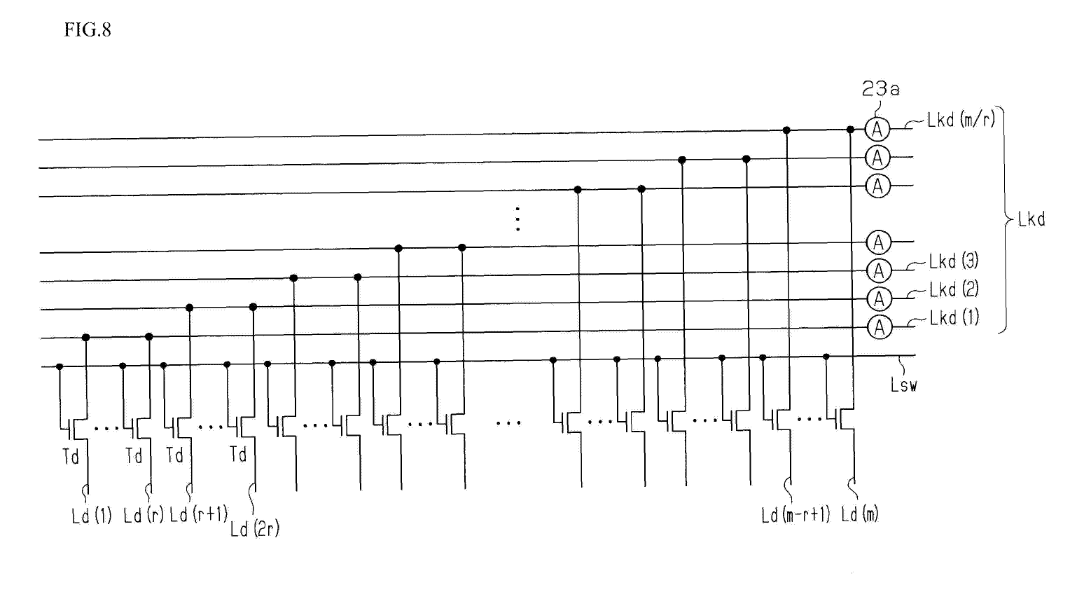

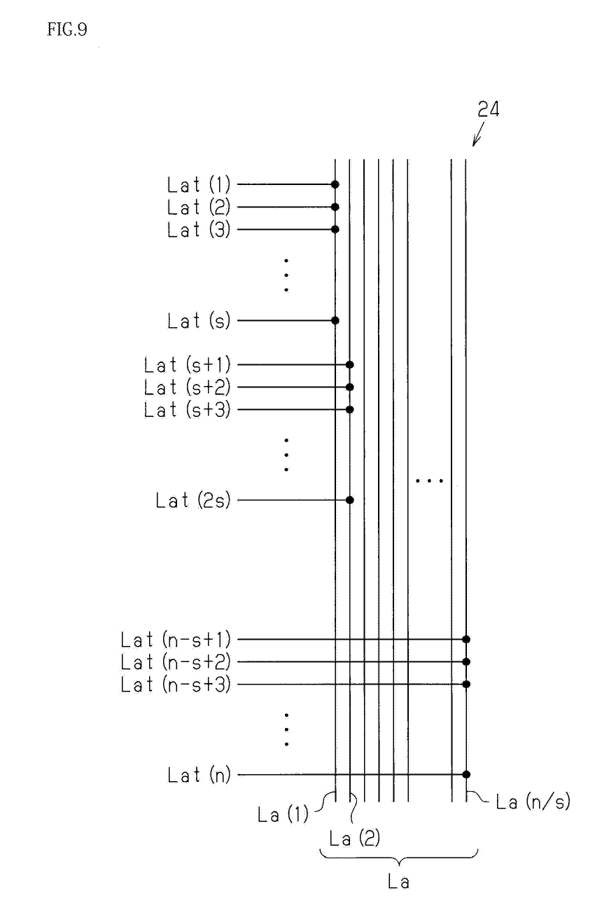

With reference to FIGS. 7 to 9, hereinafter are described, by way of an example, detailed configurations of the first block selection circuit 21, the second block selection circuit 22, the data block setting circuit 23, and the power supply block selection circuit 24. For the sake of convenience in describing a connection relationship of the first and second block selection lines Lks1 and Lks2 with the block gate line Lsw, FIG. 7 shows one block gate line Lsw common to the first and second block selection circuits 21 and 22. In FIG. 7, for the sake of convenience in describing a connection relationship of the first block selection lines Lks1 with the first pixel selection lines Ls1t and a connection relationship of the second block selection lines Lks2 with the second pixel selection lines Ls2t, row numbers are shown in brackets. Similarly, in FIG. 8, for the sake of convenience in describing a connection relationship of the data block setting lines Lkd with the data lines Ld, column numbers are shown in brackets. Also, in FIG. 9 as well, for the sake of convenience in describing a connection relationship of the power supply block selection lines La with the power supply lines Lat, row numbers are shown in brackets.

<First and Second Block Selection Circuits>

As shown in FIG. 7, the first block selection circuit 21 includes n rows of first switching transistors Ts1 as an example of the first switching circuit. Each of the n rows of first switching transistors Ts1 is an n-channel transistor, similarly to the transistors provided to the pixels PIX.

The gates of the individual n rows of first switching transistors Ts1 are connected parallel to one block gate line Lsw. Of the drains of the n rows of first switching transistors Ts1, the drains of the s rows of first switching transistors Ts1 having sequential row numbers are parallelly connected to one common first block selection line Lks1. In the n/s first block selection lines Lks1, the s rows of first switching transistors Ts1 are collectively correlated with one first block selection line Lks1, so that the row numbers of the s rows of first switching transistors Ts1 connected parallel to one first block selection lines Lks1 do not overlap between the first block selection lines Lks1. The sources of the n rows of first switching transistors Ts1 are electrically connected to one of the first pixel selection lines Ls1t.

The second block selection circuit 22 includes n rows of second switching transistors Ts2 as an example of the second switching circuit. Each of the n rows of second switching transistors Ts2 is an n-channel transistor, similarly to the transistors provided to the pixels PIX.

The gates of the n rows of second switching transistors Ts2 are connected parallel to one block gate line Lsw, similarly to the first switching transistors Ts1. Of the drains of the n rows of second switching transistors Ts2, the drains of the s rows of second switching transistors Ts2 having sequential row numbers are parallelly connected to one common second block selection line Lks2. In the n/s second block selection lines Lks2, the s rows of second switching transistors Ts2 are collectively correlated with one second block selection line Lks2, so that the row numbers of the s rows of second switching transistors Ts2 connected parallel to one second block selection line Lks2 do not overlap between the second block selection lines Lks2. The sources of the n rows of second switching transistors Ts2 are electrically connected to one of the second pixel selection lines Ls2t.

For example, the gates of the 1^{st}- to n^{th}-row first switching transistors Ts1 are electrically connected to one common block gate line Lsw, and the gates of the 1^{st}- to n^{th}-row second switching transistors Ts2 are also electrically connected to the same block gate line Lsw.

The drains of the 1^{st}- to s^{th}-row first switching transistors Ts1 are parallelly connected to one first block selection line Lks1(1) correlated with the 1^{st}-row first block. The source of the 1^{st}-row first switching transistor Ts1 is electrically connected to the 1^{st}-row first pixel selection line Ls1t(1), and the source of the s^{th}-row first switching transistor Ts1 is electrically connected to the s^{th}-row first pixel selection line Ls1t(s).

The drains of the 1^{st}- to s^{th}-row second switching transistors Ts2 are parallelly connected to one second block selection line Lks2(1) correlated with the 1^{st}-row first block. The source of the 1^{st}-row second switching transistor Ts2 is electrically connected to the 1^{st}-row second pixel selection line Ls2t(1), and the source of the s^{th}-row second switching transistor Ts2 is electrically connected to the s^{th}-row second pixel selection line Ls2t(s).

The drains of the (s+1)^{th}- to (2s)^{th}-row first switching transistors Ts1 are parallelly connected to one first block selection line Lks1(2) correlated with the 2^{nd}-row first block. The source of the (s+1)^{th}-row first switching transistor Ts1 is electrically connected to the (s+1)^{th}-row first pixel selection line Ls1t(s+1), and the source of the (2s)^{th}-row first switching transistor Ts1 is electrically connected to the (2s)^{th}-row first pixel selection line Ls1t(2s).

The drains of the (s+1)^{th}- to (2s)^{th}-row second switching transistors Ts2 are parallelly connected to one second block selection line Lks2(2) correlated with the 2^{nd}-row second block. The source of the (s+1)^{th}-row second switching transistor Ts2 is electrically connected to the (s+1)^{th}-row second pixel selection line Ls2t(s+1), and the source of the (2s)^{throw} second switching transistor Ts2 is electrically connected to the (2s)^{th}-row second pixel selection line Ls2t(2s).

Thus, the drains of the (n−s+1)^{th}- to n^{th}-row first switching transistors Ts1 are parallelly connected to one first block selection line Lks1(n/s) correlated with the (n/s)^{th}-row first block. The source of the (n−s+1)^{th}-row first switching transistor Ts1 is electrically connected to the (n−s+1)^{th}-row first pixel selection line Ls1t(n−s+1), and the source of the n^{th}-row first switching transistor Ts1 is electrically connected to the n^{th}-row first pixel selection line Ls1t(n).

The drains of the (n−s+1)^{th}- to n^{th}-row second switching transistors Ts2 are parallelly connected to one second block selection line Lks2(n/s) correlated with the (n/s)^{th}-row second block. The source of the (n−s+1)^{th}-row second switching transistor Ts2 is electrically connected to the (n−s+1)^{th}-row second pixel selection line Ls2t(n−s+1), and the source of the n^{th}-row second switching transistors Ts2 is electrically connected to the n^{th}-row second pixel selection line Ls2t(n).

Thus, when the system controller 12 outputs a permission level to the block gate line Lsw, all the first switching transistors Ts1 are permitted to simultaneously transition to an on state where the first block selection line Lks1 and the first pixel selection lines Ls1t are conducted. Also, all the second switching transistors Ts2 are permitted to simultaneously transition to an on state where the second block selection line Lks2 and the second pixel selection lines Ls2t are conducted.

When, for example, the first block selection line Lks1 corresponding to the 1^{st}-row first block is selected as an inspection target in this state, a level appropriate to the inspection target is applied simultaneously across the 1^{st}-row first pixel selection line Ls1t(1) to the s^{th}-row first pixel selection line Ls1t(s), through the first switching transistors Ts1 in an on state. In contrast, when the first block selection line Lks1 corresponding to the 1^{st}-row first block is selected as a non-inspection target, the first non-selection level L1 is applied simultaneously across the 1^{st}-row first pixel selection line To Ls1t(i) to the s^{th}-row first pixel selection line Ls1t(s), through the first switching transistors Ts1 in an on state.

<Data Block Circuit>

As shown in FIG. 8, the data block setting circuit 23 includes m columns of third switching transistors Td as an example of the output circuit. Each of the m columns of third switching transistors Td is an n-channel transistor similarly to the transistors provided to the pixels PIX.

The gates of the m columns of third switching transistors Td are parallelly connected to the block gate line Lsw in a manner similar to the first and second switching transistors Ts1 and Ts2. Of the drains of the m columns of third switching transistors Td, the drains of third switching transistors Td of r columns having sequential column numbers are parallelly connected to one common data block setting line Lkd. In the m/r data block setting lines Lkd, the third switching transistors Td of r columns are collectively correlated with one data block setting line Lkd, so that the column numbers of the third switching transistors Td of r columns parallelly connected to one data block setting line Lkd do not overlap between the data block setting lines Lkd. The sources of the third switching transistors Td of m columns are electrically connected to the respective data lines Ld.

For example, the 1^{st}- to r^{th}-column gates of the third switching transistors Td are electrically connected to one common block gate line Lsw. The drains of the 1^{st}- to r^{th}-column third switching transistors Td are parallelly connected to one data block setting line Lkd(1) corresponding to the 1^{st}-column data block. The source of the 1^{st}-column third switching transistor Td is electrically connected to the To 1^{st}-column data line Ld(1), and the source of the r^{th}-column third switching transistor Td is electrically connected to the r^{th}-column data line Ld(r).

The drains of the (r+1)^{th}- to (2r)^{th}-column third switching transistors Td are parallelly connected to one data block setting line Lkd(2) correlated with the 2^{nd}-column data block. The source of the (r+1)^{th}-column third switching transistor Td is electrically connected to the (r+1)^{th}-column data line Ld(r+1), and the source of the (2r)^{th}-column third switching transistor Td is electrically connected to the (2r)^{th}-column data line Ld(2r).

Thus, the drains of the (m−r+1)^{th}- to m^{th}-column third switching transistors Td are parallelly connected to one data block setting line Lkd(m/r) correlated with the (m/r)^{th}-column data block. The source of the (m−r+1)^{th}-column first switching transistor Ts1 is electrically connected to the (m−r+1)^{th}-column data line Ld(m−r+1), and the source of the m^{th}-column third switching transistor Td is electrically connected to the m^{th}-column data line Ld(m).

Further, when the system controller 12 outputs a permission level to the block gate line Lsw, all the third switching transistors Td are permitted to simultaneously transition to an on state where the data block setting lines Lkd and the data lines Ld are conducted. When the gradation level VdatB equivalent to displaying black is applied in this state to all the data block setting lines Lkd, the gradation level VdatB equivalent to displaying black is applied simultaneously to all the data lines Ld, through the third switching transistors Td in an on state.

In this case, a sum of currents flowing through the 1^{st}-column data line Ld(1) to the r^{th}-column data line Ld(r) flows through the data block setting line Lkd(1) corresponding to the 1^{st}-column data block. A sum of currents flowing through the (r+1)^{th}-column data line Ld(r+1) to the (2r)^{th}-column data line Ld(2r) flows through the data block setting line Lkd(2) corresponding to the 2^{nd}-column data block. A sum of currents flowing through the (m−r+1)^{th}-column data line Ld(m−r+1) to the m^{th}-column data line Ld(m) flows through the data block setting line Lkd(m/r) corresponding to the (m/r)^{th}-column data block. The current measurement unit 23a of the system controller 12 measures the current flowing through each of the ink data block setting lines Lkd to store the measurements, as the detection current I, on a data-block basis.

<Power Supply Block Circuit>

As shown in FIG. 9, in the power supply block selection circuit 24, the s power supply lines Lat are parallelly connected to each of the n/s power supply block selection lines La. For example, the 1^{st}-row power supply line Lat(1) to the s^{th}-row power supply line Lat(2) are parallelly connected to the power supply block selection line La corresponding to the 1^{st}-row power supply block. The (s+1)^{th}-row power supply line Lat(s+1) to the (2s)^{th}-row power supply line Lat(2s) are parallelly connected to the power supply block selection line La corresponding to the 2^{nd}-row power supply block. Thus, the (n−s+1)^{th}-row power supply line Lat(n−s+1) to the n^{th}-row power supply line Lat(n) are parallelly connected to the power supply block selection line La corresponding to the (n/s)^{th}-row power supply block.

When the system controller 12 applies the light emission level Vcss to the power supply block selection line La corresponding to the 1^{st}-row power supply block, for example, through the power supply driver 15, the light emission level Vcss is applied simultaneously across the 1^{st}-row power supply line Lat(1) to the s^{th}-row power supply line Lat(s). At the same time, when the system controller 12 applies the writing level Vccw to the power supply block selection lines La corresponding to the 2^{nd}- and the subsequent-order-row power supply blocks, through the power supply driver 15, the writing level Vccw is applied simultaneously across the (s+1)^{th}-row power supply line Lat(s+1) to the n^{th}-row power supply line Lat(n).

<Advantageous Effects of EL Device>

An example of a method of driving a thin film transistor array device and a method of driving an EL device will be described on the basis of the operation of the EL device in the block inspection process performed during the block driving period and the operation of the EL device performed during the gradation driving period.

<Block Driving Period>

Firstly, in the block inspection process, the system controller 12 outputs a permission level to the block gate line Lsw, and all of the first, second and third switching transistors Ts1, Ts2 and Td are permitted to transition to an on state.

Subsequently, the system controller 12 selects the first and second block selection lines Lks1 and Lks2 and the power supply block selection lines La corresponding to the 1^{st}-row row block as inspection targets. Further, the system controller 12 selects all the data block setting lines Lkd as inspection targets. Thus, the system controller 12 executes the selection operation and the detection operation described above for all the pixel circuits DC included in the 1^{st}-row row block to obtain inspection results of the m/r pixel blocks included in the 1^{st}-row row block.

Then, the system controller 12 repeats row block selection to select one row block from the n/s row blocks in order of row number, for the 2^{nd}- to (n/s)^{th}-row row blocks, to obtain inspection results for all of the pixel blocks. Thus, the block inspection process, which is a pixel-block basis inspection of the pixels PIX, is terminated, the pixel block being a set of pixels PIX.

In the block inspection process, when all the pixel blocks have been confirmed as to whether they are normal and when a pixel block not having a normal inspection result has been found, the pixel block in question is handled as a re-inspection block. Then, the re-inspection block is subjected to a pixel PIX basis inspection finer than a pixel-block basis inspection, i.e. subjected to a specific inspection process.

In the specific inspection process, firstly, the system controller 12 outputs a prohibition level to the block gate line Lsw to permit all the first, second and third switching transistors Ts1, Ts2, and Td to transition to an off state.

Subsequently, the system controller 12 selects the first and second pixel selection lines Ls1t and Ls2t and the power supply lines Lat included in the re-inspection block as inspection targets, and also selects all of the data lines Ld as inspection targets. In this case, an inspection probe provided to an external measuring device measures the current flowing through all the data lines Ld. Thus, the external measuring device obtains the inspection results of the m/r pixel blocks included in the re-inspection block.

<Gradation Driving Period>

When the system controller 12 outputs a prohibition level to the block gate line Lsw, all of the first, second and third switching transistors Ts1, Ts2, and Td are permitted to transition to an off state. Thus, the system controller 12 prohibits pixel-block basis driving of the pixels PIX to establish the gradation driving period.

Subsequently, the system controller 12 executes writing operation to all the pixels PIX included in one selection row, in order of row number, for the 1^{st}- to n^{th}-row selection rows, followed by executing light emission operation to the selection rows finished with the writing operation. Thus, the system controller 12 executes the writing operation and the light emission operation to all the pixels PIX included in the EL panel 11.

According to the above embodiment, the advantageous effects listed below can be obtained.

(1) All the pixel circuits DC included in one pixel block can be simultaneously confirmed to be in normal operation. Therefore, time taken for specifying normal pixel circuits DC can be shortened comparing with the case of driving s rows×r columns of pixel circuits DC one by one.

(2) The output of the s rows×m columns of pixel circuits DC included in one row block can be collected on a column-block basis. Therefore, time taken for specifying the area where the normally driving pixel circuits DC are located is shortened comparing with the case of obtaining column-basis output of the s rows×m columns of pixel circuits DC.

(3) With a permission level being outputted to the block gate line Lsw, row-block basis driving and column-block basis output are permitted at the same timing. In addition, with a prohibition level being outputted to the block gate line Lsw, row-block basis driving and column-block basis output are prohibited at the same timing as well. As a result, row-block basis driving and column-block basis output are is readily permitted or prohibited.

(4) When part of the s rows×r columns of pixel circuits DC included in one pixel block does not operate normally, the pixel block in question is handled as a re-inspection block. When a prohibition level is outputted to the block gate line Lsw, selection-row basis driving can be performed in the re-inspection block. As a result, whether the pixel circuits DC operate normally can be confirmed in a region finer than a pixel block.

(5) Since the system controller 12 measures row-block basis driving and column-block basis output, load imposed on the outside, such as selections of inspection targets and synchronization of the selections, is reduced in inspecting the pixel circuits DC, comparing with a configuration where the measurements are performed by an external measuring device.

The foregoing embodiment can be modified and implemented as follows.

<Mode of Inspection>

The inspection of the pixel circuits DC is not limited to the off characteristics inspection of the drive transistor T1 and the off characteristics inspection of the holding transistor, but may be, for example, an off characteristics inspection of the selection transistor T3 or an on characteristics inspection of the drive transistor T1. Such a mode of inspection can achieve advantageous effects similar to those indicated by items (1) to (5) above.

<Off Characteristics Inspection of Selection Transistor>

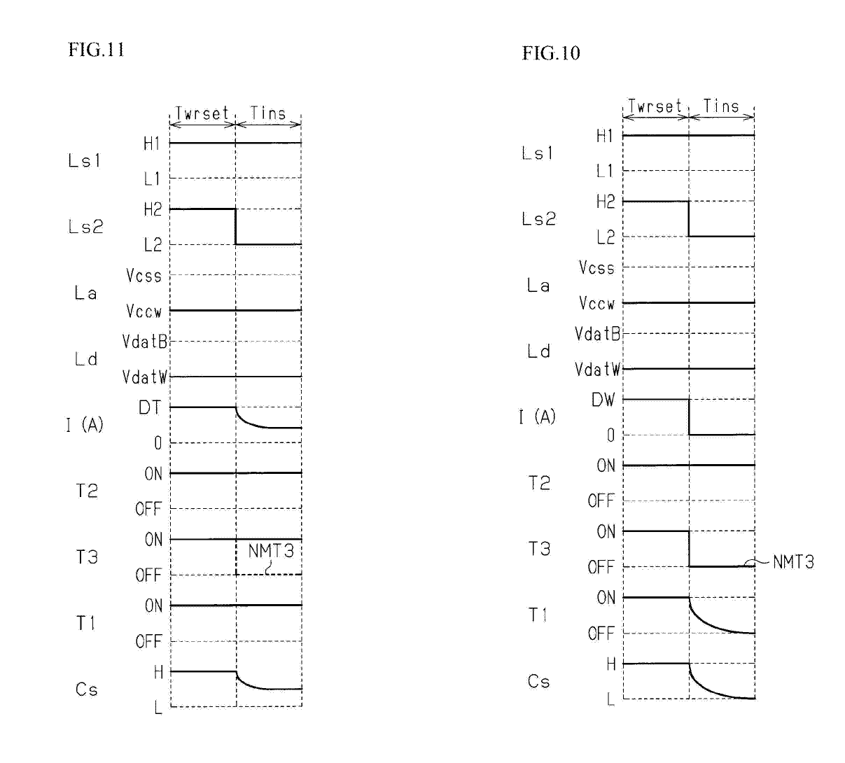

FIGS. 10 and 11 are timing diagrams illustrating transition of the detection current I in an off characteristics inspection of the selection transistor T1 FIG. 10 is a timing diagram illustrating transition of the detection current I when the selection transistor T3 has normal off characteristics. FIG. 11 is a timing diagram illustrating transition of the detection current I when an off current flows through the selection transistor T3.

As shown in FIG. 10, in the process of inspecting off characteristics of the selection transistor T3, a white resetting period Twrset in which white reset operation is executed and the detection period Tins in which inspection operation is executed are established in this order.

Firstly, during the white resetting period Twrset, the first selection level H1 is applied to the first pixel selection lines Ls1t, and the second selection level H2 is applied to the second pixel selection lines Ls2t. Thus, the holding transistor T2 and the selection transistor T3 are permitted to transition to an on state, and with the transition of the holding transistor T2 to an on state, the drive transistor T1 is also permitted to transition to an on state. Further, the writing level Vccw is applied to the power supply lines Lat, and the gradation level VdatW equivalent to displaying white is applied to the data lines Ld. In this case, since the gradation level VdatW equivalent to displaying white is at a level sufficiently lower than the writing level Vccw, a current DW based on the difference between the gradation level VdatW and the writing level Vccw flows through the data lines Ld as the detection current I. Thus, a voltage at the high level H equivalent to the difference between the gradation level VdatW and the writing level Vccw is written into the holding capacitor Cs.

Subsequently, during the detection period Tins, the level of the second pixel selection lines Ls2t is changed from the second selection level H2 to the second non-selection level L2 to cause the selection transistor T3 to transition to an off state.

In this case, when the off characteristics of the selection transistor T3 are normal, current flows through the source-drain of the drive transistor T1, and electric charge accumulated in the holding capacitor Cs is discharged, so that the level of the source of the drive transistor T1 is approximated to the level of the drain of the drive transistor T1. On the other hand, since the selection transistor T3 is in an off state, the detection current I does not flow through the data lines Ld. Further, when the source-drain voltage of the drive transistor T1 becomes not more than a threshold of the drive transistor T1, the drive transistor T1 is permitted to transition to an off state and the voltage that has been written into the holding capacitor Cs is permitted to transition to a low level.

As a result, when the off characteristics of the selection transistor T3 are normal, the detection current I detected by the current measurement unit 23a immediately falls from the current DW to approximately 0, as indicated by a solid line NMT3, on or after the time point of applying the second non-selection level L2.

In contrast, as shown in FIG. 11, when a non-negligible off current flows through the selection transistor T3, and when the second non-selection level L2 is applied thereto during the detection period Tins, firstly, a current flows through the source-drain of the drive transistor T1 and electric charge accumulated in the holding capacitor Cs is discharged. However, the selection transistor T3 electrically connects between the data lines Ld, to which the gradation level VdatW is applied, and the source of the drive transistor T1. Accordingly, a current equivalent to the drain current of the drive transistor T1 flows through the data lines Ld. Thus, the current flowing through the data lines Ld falls by an amount corresponding to the difference between the on current of the selection transistor T3 and the off current of the selection transistor T3. Further, the voltage written into the holding capacitor Cs also falls by an amount corresponding to the voltage across the source-drain of the selection transistor T3.

As a result, when the off characteristics of the selection transistor T3 are abnormal, the detection current I detected by the current measurement unit 23a becomes larger than when the off characteristics of the selection transistor T3 are normal but becomes smaller than the current DW, on or after the time point of applying the second non-selection level L2.

<On Characteristics Inspection of Drive Transistor>

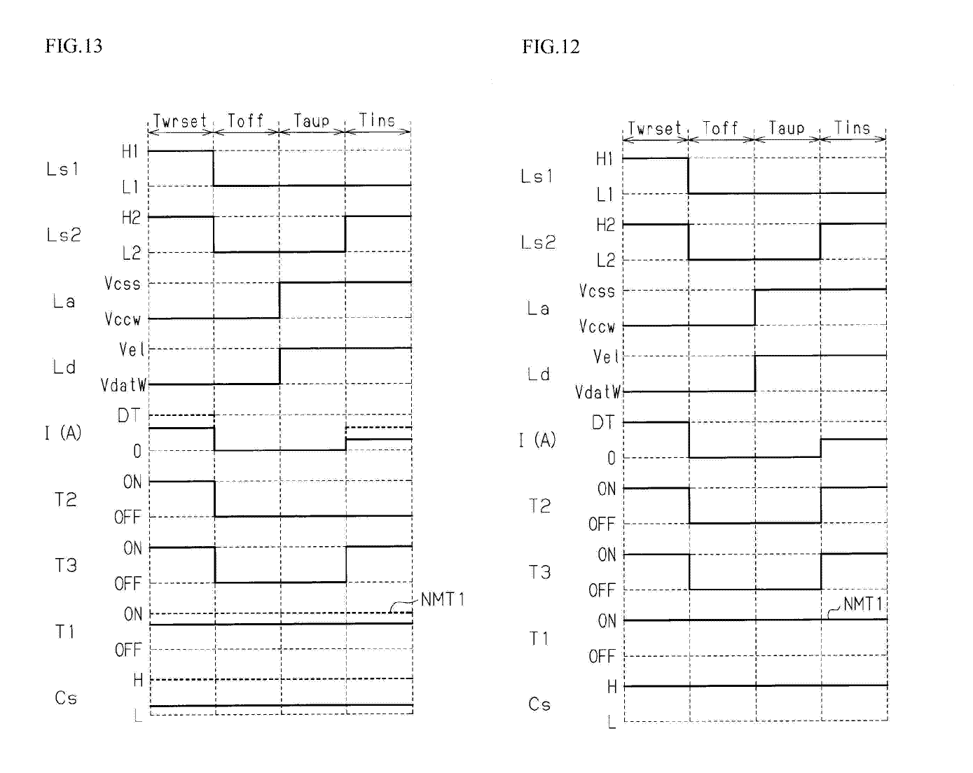

FIGS. 12 and 13 are timing diagrams illustrating transition of the detection current I in an on characteristics inspection process conducted for the drive transistor T1. FIG. 12 is a timing diagram illustrating transition of the detection current I when the selection transistor T3 has normal off characteristics. FIG. 13 is a timing diagram illustrating transition of the detection current I when an off current flows through the selection transistor T3.

As shown in FIG. 12, in the on characteristics inspection process conducted for the drive transistors T1, a white resetting period Twrset described above, an off period Toff in which an off operation is executed, a gradation application period Taup in which an anode level Vel is applied, and a detection period Tins in which the inspection operation is executed are set in this order.

Firstly, in the off period Toff, the first non-selection level L1 is applied to the first pixel selection lines Ls1t, and the second non-selection level L2 is applied to the second pixel selection lines Ls2t. Thus, the holding transistor T2 and the selection transistor T3 are permitted to transition to an off state. On the other hand, since the holding capacitor Cs holds the voltage at the high level H written by the white resetting operation, only the drive transistor T1 maintains an on state.

Subsequently, during the gradation application period Taup, the light emission level Vcss is applied to the power supply lines Lat. Further, the anode level Vel higher than the gradation level VdatW corresponding to displaying white is applied to the data lines Ld, the anode level Vel being applied to the anode of the EL element OEL. During this period as well, the holding transistor T2 and the selection transistor T3 maintain an off state, while only the drive transistor T1 maintains an on state.

Further, during the detection period Tins, the second non-selection level L2 is changed to the second selection level H2 for only the second pixel selection lines Ls2t, and thus only the selection transistor T3 is permitted to transition from the off to on state. In to addition, in a state where the holding transistor T2 is maintained to be in an off state, only the selection transistor T3 is switched from the off to on state to electrically connect the power supply lines Lat to the data lines Ld, through the drive transistor T1 and the selection transistor T3. As a result, the current flowing through the EL element OEL, to which the anode level Vel is applied, flows through the data lines Ld, as the detection current I.

In contrast, as shown in FIG. 13, when the on current of the drive transistor T1 is small, the current flowing through the data lines Ld during the white resetting period Twrset is smaller than in the case where the on characteristics of the drive transistor T1 are normal. Further, the voltage written into the holding capacitor Cs by the white resetting operation also becomes lower than in the case where the on characteristics of the drive transistor T1 are normal. As a result, the detection current I flowing through the data lines Ld during the detection period Tins becomes smaller than in the case where the on characteristics of the drive transistor T1 are normal. Since such reduction in the detection current I is also recognized when a leak current becomes higher in the holding capacitor Cs, the present inspection can also be used as an inspection to the holding characteristics of the holding capacitor Cs.

<Block>

Row blocks are not limited to the first blocks but may be the second blocks or may be the power supply blocks. For example, when the row blocks are configured as the second blocks, one selection row is made up of one second pixel selection line Ls2t and a plurality of pixels PIX connected parallel to the second pixel selection line Ls2t. Alternatively, for example, when the row blocks are configured as the power supply blocks, one selection row is made up of one power supply line Lat and a plurality of pixels PIX connected parallel to the power supply line Lat, and a switching circuit is provided between one power supply block selection line La and the power supply lines Lat parallelly connected thereto.

The number of selection columns configuring a row block only needs to be 2 or more. In this case, the number may be equal to or different from each other between row blocks. Alternatively, the number in one or more row blocks may be different from the number in the rest of the row blocks.

The number of output columns configuring a column block only needs to be 2 or more. In this case, the number may be equal to or different from each other between column blocks. Alternatively, the number in one or more column blocks may be different from the number in the rest of the column blocks.

Each of the plurality of output columns configuring the column block may be made up, for example, of one data line and one pixel PIX. Further, the number of pixels PIX provided to each of the plurality of output columns may be different between output columns. For example, the direction in which the pixels PIX are arrayed in the EL device is not limited to the two dimensional direction, but may be a one dimensional direction. The EL device may be an exposure device in which a plurality of pixels PIX arrayed in one dimensional direction are installed in a photoconductor drum. When the thin film transistor array device is applied to such an EL device, each of the plurality of output columns configuring a column block is made up of one data line and one pixel PIX.

<Switching Circuit>

At least one of the gates of the first, second and third switching transistors Ts1, Ts2 and Td may be connected to the system controller 12 through a line different from the block gate line Lsw. The gates of the first, second and third switching transistors Ts1, Ts2 and Td may be connected to the system controller 12 through lines different from each other. With the configuration having such connection as well, advantageous effects similar to those shown in the items (1) and (2) above can be obtained, as long as a permission level and a prohibition level are ensured to be outputted to the gates of the first, second and third switching transistors Ts1, Ts2 and Td at the same timing.

At least one of the first, second and third switching transistors Ts1, Ts2 and Td may be a p-channel transistor. The channel type of the first, second and third switching transistor Ts1, Ts2 and Td is preferably the same as the channel type of the transistors provided to each pixel PIX. As long as the switching transistors are of such a channel type, the transistors provided to the pixel PIX and the transistors provided to the switching circuits can be fabricated through the same fabrication process.

<Pixel Circuit>

The EL element OEL whose light emission is controlled by the pixel circuit DC may be, for example, an organic or inorganic EL element, or may be a light emitting diode, as long as it is a current driving element.

The element circuit is not limited to the pixel circuit DC including the thin film transistors and the EL element OEL, but may be, for example, a sensor circuit including thin film transistors and a sensor element. Objects to which the thin film transistor array device is applied are not limited to EL devices, but may be sensor devices including a plurality of sensor circuits.

For example, the sensor device can be implemented by any one of a biosensor device, temperature sensor device, illuminance sensor device, and concentration sensor device. For example, the sensor element can be implemented by any one of a biosensor element, temperature sensor element, illuminance sensor element, and concentration sensor element, in conformity with the objects to be measured by the sensor device.

Specifically, the element circuit only needs to have a configuration of enabling display and measurement through selection of an element selection line connected to the element circuit. The sensor element provided to the element circuit only needs to have a configuration of enabling measurement through selection of a thin film transistor provided to the element circuit.

The drive transistor T1, the holding transistor T2, and the selection transistor T3 may be a p-channel thin film transistor. In this case, the source of the drive transistor T1 is electrically connected to the power supply line Lat, and the drain of the drive transistor T1 is electrically connected to the EL element OEL. The source of the holding transistor T2 is electrically connected to the source of the drive transistor T1, and the drain of the holding transistor T2 is electrically connected to the gate of the drive transistor T1. Further, the drain of the selection transistor T3 is electrically connected to the data line Ld, and the source of the selection transistor T3 is electrically connected to the drain of the drive transistor T1.

The pixel circuit DC provided to each pixel PIX is not limited to the 3Tr/1C type described above. The mode of connection between the plurality of thin film transistors may be different from this mode. For example, one pixel circuit DC may be of 2Tr/1C type which is composed of a drive transistor and a holding transistor, as two thin film transistors, and one capacitor element. That is, a pixel circuit may have a configuration from which the selection transistor T3 is omitted. Alternatively, the pixel circuit provided to a pixel PIX may be configured to include a drive transistor and a holding transistor, as well as four or more thin film transistors.

In short, each of the plurality of selection rows configuring one row block only needs to be configured by one pixel circuit having thin film transistors and one pixel selection line connected to the gates of the thin film transistors, with all the pixel selection lines configuring the one row block being parallelly connected to one row block selection line.

<System Controller>

During the block driving period of the EL panel 11, using the sequence function of the system controller 12, the m/r data block setting lines Lkd may be selected as inspection targets at different time points. For example, using the sequence function of the system controller 12, the m/r data block setting lines Lkd may be selected as inspection targets in order of column number to cause the current measurement unit 23a to measure the current flowing through the data block setting lines Lkd in order of column number. In this case, using the sequence function of the system controller 12, the row blocks, as targets of inspection, are switched from one to another every time the measurement of the detection current I in all the data block setting lines Lkd is terminated to thereby synchronize measurement of the detection current I in the m/r data block setting lines Lkd with selection of a row block, as a target of inspection.

The switching of the row blocks, i.e. targets of inspection, and switching of the column blocks, i.e. targets of inspection, are not limited to be performed in order of row number or column number, but the order may be appropriately changed by the system controller 12 or an external measuring device.

During the block driving period of the EL panel 11, the n/s second block selection lines Lks2 may be selected as detection targets or non-inspection targets by an external measuring device other than the system controller 12. The n/s second block selection lines Lks2 may be maintained at a constant level during the block driving period of the EL panel 11, regardless of the switching of the row blocks. For example, when the off characteristics of the drive transistors T1 are inspected, all the n/s second block selection lines Lks2 may continuously select the inspection targets to which the second selection level H2 has been applied, regardless of the switching of the row blocks.

During the block driving period of the EL panel 11, application of the writing level Vccw and the light emission level Vcss to the n/s power supply block selection lines La may also be performed by an external measuring device other than the system controller 12 or the power supply driver 15. The n/s power supply block selection lines La may be maintained at a constant level during the block driving period of the EL panel 11, regardless of the switching of the row blocks. For example, when the off characteristics of the selection transistors T3 are inspected, all the n/s power supply block selection lines La may continuously select the inspection targets to which the writing level Vccw has been applied, regardless of the switching of the row blocks.

Further, during the block driving period of the EL panel 11, the n/s first block selection lines Lks1 may be selected as inspection target and non-inspection target by an external measuring device other than the system controller 12. When the second block is configured as an example of a row block, the n/s first block selection lines Lks1 may be maintained at a constant level during the block driving period of the EL panel 11, regardless of the switching of the row blocks. For example, when the off characteristics of the selection transistors T3 are inspected, all the n/s first block selection lines Lks1 may continuously select the inspection targets to which the first selection level H1 has been applied, regardless of the switching of the row blocks.

During the block driving period of the EL panel 11, measurement of the current flowing through the individual m/r data block setting lines Lkd may be performed by an external measuring device other than the system controller 12.

In short, whether a row block may be defined as the first block, or may be defined as the second block, or may be defined as the power supply block, all the pixel circuits included in one row block selected from the row blocks only need to be the targets of simultaneous driving. As described in the above embodiment, when the row numbers of the power supply lines Lat connected parallel to one power supply block selection line La are selected and when no switching circuit is provided between the power supply block selection line La and the power supply lines Lat, the row numbers of the power supply lines Lat configuring the power supply block preferably agree with the row numbers of the first pixel selection lines Ls1t configuring the first block. Further, the row numbers of the power supply lines Lat configuring the power supply block preferably agree with the row numbers of the second pixel selection lines Ls2t configuring the second block.

With the row blocks being defined in this way, the voltage level applied to the power supply lines Lat can be readily changed on a row-block basis. Thus, in inspecting a selected row block, the level applied to the power supply lines Lat does not have to agree with the level applied to the selected row block. Further, the voltage level applied to the second pixel selection lines Ls2t can also be readily changed on a row-block basis. Thus, in inspecting a selected row block, the level applied to the second pixel selection lines Ls2t does not have to agree with the level applied to the selected row block.

In this case, inspection targets and non-inspection targets may be selected by an external measuring device other than the system controller 12. Further, the selection level to select one of the row blocks only needs to be applied from outside to the block selection lines, one by one, and row-block basis driving permission targeting to simultaneously drive all the pixel circuits included in the row block only needs to be determined by the switching circuit.

In EL device fabrication processes, typically, the operations of a plurality of pixel circuits are inspected for each EL device. In this case, since a high number of pixel circuits are included in one EL device, e.g. several hundreds of thousands to several millions, it takes a lot of time to confirm whether the plurality of individual pixel circuits in the EL device are normal.

The technique of the present disclosure has an object of providing a thin film transistor array device capable of reducing time taken for confirming whether a plurality of individual element circuits are normal, an EL device, a sensor device, a method of driving a thin film transistor array device, a method of driving an EL device, and a method of driving a sensor device.

An aspect of a thin film transistor array device in the technique of the present disclosure includes a plurality of row blocks each including a plurality of selection rows, each of the plurality of selection rows having at least one element circuit including a thin film transistor, and one element selection line to which a gate of the thin film transistor is connected. The aspect also includes a row block selection circuit including row block selection lines in which each row block selection line is provided to a corresponding row block, with all the element selection lines included in the row block being parallelly connected to the row block selection line. The row block selection circuit is configured to apply a selection level from outside to the row block selection lines one by one, the selection level being for selecting one row block from among the row blocks. The row block selection circuit further includes a switching circuit to switch a conduction state to a non-conduction state, or vice versa, between the element selection line and the row block selection line, simultaneously for all the element selection lines, and the switching circuit is configured to permit row-block basis driving with which all the element circuits included in one row block that has been selected through application of the selection level are targeted to be simultaneously driven, in the conduction state, and to permit selection-row basis driving with which the row-block basis driving is prohibited so that all the element circuits included in one selection row are simultaneously driven, in the non-conduction state.

An aspect of an EL device in the technique of the present disclosure includes a thin film transistor array device including a plurality of element circuits each including a thin film transistor and an EL element.

An aspect of a sensor device in the technique of the present disclosure includes a thin film transistor array device including a plurality of element circuits each including a thin film transistor and a sensor element.

An aspect of a method of driving a thin film transistor array device in the technique of the present disclosure includes: a plurality of row blocks each including a plurality of selection rows, each of the plurality of selection rows having at least one element circuit including a thin film transistor, and one element selection line to which a gate of the thin film transistor is connected; and a row block selection circuit including row block selection lines in which each row block selection line is provided to a corresponding row block, with all the element selection lines included in the row block being parallelly connected to the row block selection line, and including a switching circuit to switch a conduction state to a non-conduction state, or vice versa, between the row block selection line and the element selection line, simultaneously for all the element selection lines. The method includes steps of: driving the switching circuit to establish conduction between the row block selection line and the element selection line, for all the element selection lines; and applying a selection level to the row block selection lines one by one, the selection level being for selecting one row block from among the row blocks, and causing the row block selection circuit to simultaneously select all the element circuits included in one row block that has been selected through application of the selection level.

An aspect of a method of driving an EL device in the technique of the present disclosure includes: a plurality of row blocks each including a plurality of selection rows, each of the plurality of selection rows having at least one element circuit including an EL element and a thin film transistor, and one element selection line to which a gate of the thin film transistor is connected; and a row block selection circuit including row block selection lines in which each block selection line is provided to a corresponding row block, with all the element selection lines included in the row block being parallelly connected to the row block selection line, and including a switching circuit to switch a conduction state to a non-conduction state, or vice versa, between the row block selection line and the element selection line, simultaneously for all the element selection lines. The method includes steps of: driving the switching circuit to establish conduction between the row block selection line and the element selection line, for all the element selection lines; and applying a selection level to the row block selection lines one by one, the selection level being for selecting one row block from among the row blocks, and causing the row block selection circuit to simultaneously select all the element circuits included in one row block that has been selected through application of the selection level.

An aspect of a method of driving a sensor device in the technique of the present disclosure includes: a plurality of row blocks each including a plurality of selection rows, each of the plurality of selection rows having at least one element circuit including a sensor element and a thin film transistor, and one element selection line to which a gate of the thin film transistor is connected; and a row block selection circuit including row block selection lines in which each row block selection line is provided to a corresponding row block, with all the element selection lines included in the row block being parallelly connected to the row block selection line, and including a switching circuit to switch a conduction state to a non-conduction state, or vice versa, between the row block selection line and the element selection line, simultaneously for all the element selection lines. The method includes steps of: driving the switching circuit to establish conduction between the row block selection line and the element selection line, for all the element selection lines; and applying a selection level to the row block selection lines one by one, the selection level being for selecting one row block from among the row blocks, and causing the row block selection circuit to simultaneously select all the element circuits included in one row block that has been selected through application of the selection level.

According to an aspect of the technique of the present disclosure, driving in each of the element circuits is switched between row-block basis driving and selection-row basis driving. According to the row-block basis driving, all of the element circuits included in one of the row blocks are simultaneously driven. Thus, when all of the element circuits included in one row block operate normally, it is confirmed at the same time that each of the plurality of element circuits is normal. Therefore, comparing with the case of driving a plurality of element circuits included in one row block one by one, time taken for specifying normal element circuits is shorter. When part of the plurality of driving circuits included in one row block does not operate normally, the row block including the element circuit not operating normally is specified. Further, according to the selection-row basis driving, since whether the element circuits operate normally can be confirmed in a region finer than a block, an element circuit not operating normally is readily specified.

In another aspect of a thin film transistor array device in the technique of the present disclosure, each of the selection rows includes a plurality of element circuits and one element selection line to which a gate of the thin film transistor of each of the plurality of element circuits is parallelly connected. Further, the device includes a plurality of column blocks, each column block being made up of a plurality of output columns, each of the plurality of output columns having one data line intersecting all the row blocks, and the plurality of element circuits located in an area where each of the element selection lines intersects the data line and parallelly connected to one data line. The device also includes a column block setting circuit including column block selection lines in which each column block selection line is provided to a corresponding column block, with all the data line included in the column block being parallelly connected to the row block selection line. The data line outputs a current based on driving of the plurality of element circuits parallelly connected to the data line, and the column block selection line outputs a sum of currents outputted by the plurality of data lines parallelly connected to the column block selection line, as a column-block basis current. The column block setting circuit further includes an output circuit to switch a conduction state to a non-conduction state, or vice versa, between the data line and the column block selection line, simultaneously for all the data lines. The output circuit is configured to permit column-block basis output with which a column-block basis current is outputted from all the column block selection lines, in the conduction state established between the data line and the column block selection line, and to prohibit the column-block basis output, in the non-conduction state established between the data line and the column block selection line.

According to another aspect of a thin film transistor array device in the technique of the present disclosure, column-block basis output is switched to prohibition of the output, or vice versa, for the outputs of all the element circuits. According to the column-block basis output, of the element circuits included in one column block, the plurality of element circuits included in one selected row block are all driven simultaneously, and a sum of the currents based on the driving of the plurality of element circuits is outputted as a column-block basis current. In this case, in an area where one row block and one column block intersect, a plurality of element circuits are still included. Therefore, advantageous effects similar to those described above are obtained. Moreover, since the outputs of the plurality of element circuits included in one row block are collected on a column-block basis, time taken for specifying the region where normally driving element circuits are located is much shorter comparing with the case where the outputs of the plurality of element circuits included in one row block are obtained on a column basis.

Another aspect of a thin film transistor array device in the technique of the present disclosure further includes one block gate line to which the row block selection circuit and the column block setting circuit are parallelly connected. When a permission level is outputted to the block gate line, the row block selection circuit establishes a conduction state between the element selection line and the row block selection line, simultaneously for all the element selection lines, and the column block setting circuit establishes a conduction state between the data line and the column block selection line, simultaneously for all the data lines. Further, when a prohibition level is outputted to the block gate line, the row block selection circuit establishes a non-conduction state between the element selection line and the row block selection line, simultaneously for all the element selection lines, and the column block setting circuit establishes a non-conduction state between the data line and the column block selection line, simultaneously for all the data lines.

According to another aspect of a thin film transistor array device in the technique of the present disclosure, with a permission level being outputted to the block gate line, row-block basis driving performed by the row block selection circuit and column-block basis output performed by the column block setting circuit are permitted at the same timing. Further, with a prohibition level being outputted to block gate line, the row-block basis driving performed by the row block selection circuit and the column-block basis output performed by the column block setting circuit are also prohibited at the same timing. As a result, row-block basis driving and column-block basis output are readily permitted or prohibited.

In another aspect of a thin film transistor array device in the technique of the present disclosure, the element circuit includes: a holding capacitor, a drive transistor including a gate and a source connected via the holding capacitor to flow a current according to a voltage held by the holding capacitor, a holding transistor that is the thin film transistor to switch a conduction state to a non-conduction state, or vice versa, between a gate of the drive transistor and a drain of the drive transistor, and a selection transistor to switch a conduction state to a non-conduction state, or vice versa, between a source of the drive transistor and a data line. Further, the element selection line is a first element selection line connected to a gate of the holding transistor. The thin film transistor array device further includes a second element selection line connected to a gate of the selection transistor and configured to enable application of a level different from that of the first element selection line.

According to another aspect of a thin film transistor array device in the technique of the present disclosure, the holding transistor and the selection transistor are separately turned on or turned off. Thus, whether the holding transistor is normal or whether the selection transistor is normal can be confirmed.

In another aspect of a thin film transistor array device in the technique of the present disclosure, the row block is a first block; the selection row is a first selection row; the row block selection line is a first block selection line; the row block selection circuit is a first block selection circuit; the switching circuit is a first switching circuit; the thin film transistor array device further includes: a plurality of the second blocks each including a plurality of second selection rows, each of the plurality of second selection rows having the element circuit and one second element selection line to which a gate of the selection transistor is connected, and a second block selection circuit including second block selection lines in which each second block selection line is provided to a corresponding second block, with all the second element selection lines included in the second block being parallelly connected to the second block selection line. Further, the second block selection circuit is configured to apply a selection level from outside to the second block selection lines one by one, the selection level being for selecting one second block from among the second blocks, the one second block having the element circuit that is the same as that in the first block selected by the first block selection circuit; the second block selection circuit further includes a second switching circuit to switch a conduction state to a non-conduction state, or vice versa, between the second element selection line and the second block selection line, simultaneously for all the second element selection lines; and the second switching circuit is configured to permit second-block basis driving with which all the element circuits included in the selected one second block are targeted to be simultaneously driven, in the conduction state, and to permit second-row basis driving with which the second-block basis driving is prohibited so that all the element circuits included in one second selection row are simultaneously driven, in the non-conduction state.

In another aspect of a thin film transistor array device in the technique of the present disclosure, the first block selected by the first block selection circuit and the second block selected by the second block selection circuit have element circuits in common. Therefore, whether the holding transistor is normal or whether the selection transistor is normal can be confirmed by block driving performed by the first and second block selection circuits.

According to the technique of the present disclosure, time taken for confirming whether or not each of a plurality of element circuits is normal can be reduced.

### REFERENCE SIGNS LIST

I: detection current, Cs: holding capacitor, DC: pixel circuit, DT: turn-off current, H1: first selection level, H2: second selection level, Id: drive current, L1: first non-selection level, L2: second non-selection level, La: power supply block selection line, Ld: data line, T1: drive transistor, T2: holding transistor, T3: selection transistor, Td: third switching transistor, Lat: power supply line, Lkd: data block setting line, Ls1: first specific pixel selection line, Ls2: second specific pixel selection line, Lsw: block gate line, OEL: EL element, Toff: turned off period, PIX: pixel, PLd: data line terminal, Ts1: first switching transistor, Ts2: second switching transistor, VAN: anode level, VEE: reference level, Vel: anode level, Vgs: gate-source voltage, Lks1: first block selection line, Lks2: second block selection line, Ls1t: first pixel selection line, Ls2t: second pixel selection line, PLs1: first connection terminal, PLs2: second connection terminal, Tins: detection period, Vccw: writing level, Vcss: light emission level, SCON1: first selection control signal, SCON2: second selection control signal, SCON3: power supply control signal, SCON4: data control signal, Tbrset: black resetting period, Twrset: white resetting period, 10: EL device, 11: EL panel, 12: system controller, 13: first selection driver, 14: second selection driver, 15: power supply driver, 16: data driver, 21: first block selection circuit, 22: second block selection circuit, 23: data block setting circuit, 23a: current measurement unit, 24: power supply block selection circuit.

Obviously, numerous modifications and variations of the present invention are possible in light of the above teachings. It is therefore to be understood that within the scope of the appended claims, the invention may be practiced otherwise than as specifically described herein.

What is claimed is:

1. A thin film transistor array device, comprising:
a plurality of row blocks each including a plurality of selection rows, each of the selection rows having at least one element circuit including a thin film transistor, and an element selection line connected to a gate of the thin film transistor; and
a row block selection circuit including a plurality of row block selection lines each corresponding to a respective one of the row blocks such that all the element selection lines in the respective one of the row blocks are parallelly connected to a respective one of the row block selection lines,
wherein the row block selection circuit is configured to apply, to the row block selection lines one by one, a selection level for selecting one row block from the row blocks from outside, the row block selection circuit further includes a switching circuit configured to switch between the element selection line and the row block selection line to change between a conduction state and a non-conduction state simultaneously for all the element selection lines, and the switching circuit is configured to permit row-block basis driving in the conduction state such that all the element circuits in the one row block selected by application of the selection level are simultaneously targeted to be driven and to permit selection-row basis driving in the non-conduction state such that the row-block basis driving is prohibited and that all the element circuits in a respective one of the selection rows are simultaneously driven.

2. The thin film transistor array device according to claim 1, further comprising:
a plurality of column blocks each comprising a plurality of output columns; and
a column block setting circuit including a plurality of column block selection lines each corresponding to a respective one of the column blocks,
wherein each of the selection rows includes the element circuit in a plurality and one element selection line parallelly connected to To gates of thin film transistors in the plurality of element circuits, each of the output columns has one data line intersecting all the row blocks, and the plurality of element circuits positioned in an area where each of the element selection lines intersects the data line and parallelly connected to one data line, and each of the column block selection lines is corresponding to the respective one of the column blocks such that all the data line in the respective one of the column blocks is parallelly connected to the row block selection line, the data line outputs a current based on driving of the plurality of element circuits parallelly connected to the data line, the column block selection line outputs, as a column-block basis current, a sum of currents output by the plurality of data lines parallelly connected to the column block selection line, the column block setting circuit further includes an output circuit configured to switch between the data line and the column block selection line to change between a conduction state and a non-conduction state simultaneously for all the data lines, and the output circuit is configured to permit column-block basis output in the conduction state established between the data line and the column block selection line such that a column-block basis current is output from all the column block selection lines and to prohibit the column-block basis output in the non-conduction state established between the data line and the column block selection line.

3. The thin film transistor array device according to claim 2, further comprising:
a block gate line parallelly connected to the row block selection circuit and the column block setting circuit,
wherein when a permission level is output to the block gate line, the row block selection circuit establishes a conduction state between the element selection line and the row block selection line simultaneously for all the element selection lines, and the column block setting circuit establishes a conduction state between the data line and the column block selection line simultaneously for all the data lines, and when a prohibition level is output to the block gate line, the row block selection circuit establishes a non-conduction state between the element selection line and the row block selection line simultaneously for all the element selection lines, and the column block setting circuit establishes a non-conduction state between the data line and the column block selection line simultaneously for all the data lines.

4. The thin film transistor array device according to claim 1, further comprising:
a second element selection line,
wherein the element circuit includes a holding capacitor, a drive transistor including a gate and a source connected via the holding capacitor such that a current flows according to a voltage held by the holding capacitor, a holding transistor that is the thin film transistor configured to switch between a gate and a drain of the drive transistor to change between a conduction state and a non-conduction state, and a selection transistor configured to switch between a source of the drive transistor and a data line to change between a conduction state and a non-conduction state, the element selection line is a first element selection line connected to a gate of the holding transistor, and the second element selection line is connected to a gate of the selection transistor and configured to enable application of a level different from a level of the first element selection line.

5. The thin film transistor array device according to claim 4, further comprising:
a second block selection circuit including a plurality of second block selection lines each corresponding to a respective one of the second blocks,
wherein the row block is a first block, the selection row is a first selection row, the row block selection line is a first block selection line, the row block selection circuit is a first block selection circuit, the switching circuit is a first switching circuit, the second block is provided in a plurality such that the plurality of second blocks each includes a plurality of second selection rows each having the element circuit and a second element selection line connected to a gate of the selection transistor, all the second element selection lines in the respective one of the second blocks are parallelly connected to the second block selection line, the second block selection circuit is configured to apply, to the second block selection lines one by one, a selection level for selecting one second block from the second blocks from outside, the one second block has the element circuit that is the same as the element circuit in the first block selected by the first block selection circuit, the second block selection circuit further includes a second switching circuit configured to switch between the second element selection line and the second block selection line to change between a conduction state and a non-conduction state simultaneously for all the second element selection lines, and the second switching circuit is configured to permit second-block basis driving in the conduction state such that all the element circuits in the one second block selected are targeted to be simultaneously driven, and to permit second-row basis driving in the non-conduction state such that the second-block basis driving is prohibited and that all the element circuits in one of the second selection rows are simultaneously driven.

6. An EL device, comprising:
the thin film transistor array device of claim 1 including a plurality of element circuits each including the thin film transistor and an EL element.

7. A sensor device, comprising:
the thin film transistor array device of claim 1 including a plurality of element circuits each including the thin film transistor and a sensor element.

8. The thin film transistor array device according to claim 2, further comprising:
a second element selection line,
wherein the element circuit includes a holding capacitor, a drive transistor including a gate and a source connected via the holding capacitor such that a current flows according to a voltage held by the holding capacitor, a holding transistor that is the thin film transistor configured to switch between a gate and a drain of the drive transistor to change between a conduction state and a non-conduction state, and a selection transistor configured to switch between a source of the drive transistor and a data line to change between a conduction state and a non-conduction state, the element selection line is a first element selection line connected to a gate of the holding transistor, and the second element selection line is connected to a gate of the selection transistor and configured to enable application of a level different from a level of the first element selection line.

9. The thin film transistor array device according to claim 8, further comprising:
a second block selection circuit including a plurality of second block selection lines each corresponding to a respective one of the second blocks,
wherein the row block is a first block, the selection row is a first selection row, the row block selection line is a first block selection line, the row block selection circuit is a first block selection circuit, the switching circuit is a first switching circuit, the second block is provided in a plurality such that the plurality of second blocks each includes a plurality of second selection rows each having the element circuit and a second element selection line connected to a gate of the selection transistor, all the second element selection lines in the respective one of the second blocks are parallelly connected to the second block selection line, the second block selection circuit is configured to apply, to the second block selection lines one by one, a selection level for selecting one second block from the second blocks from outside, the one second block has the element circuit that is the same as the element circuit in the first block selected by the first block selection circuit, the second block selection circuit further includes a second switching circuit configured to switch between the second element selection line and the second block selection line to change between a conduction state and a non-conduction state simultaneously for all the second element selection lines, and the second switching circuit is configured to permit second-block basis driving in the conduction state such that all the element circuits in the one second block selected are targeted to be simultaneously driven, and to permit second-row basis driving in the non-conduction state such that the second-block basis driving is prohibited and that all the element circuits in one of the second selection rows are simultaneously driven.

10. The thin film transistor array device according to claim 3, further comprising:
a second element selection line,
wherein the element circuit includes a holding capacitor, a drive transistor including a gate and a source connected via the holding capacitor such that a current flows according to a voltage held by the holding capacitor, a holding transistor that is the thin film transistor configured to switch between a gate and a drain of the drive transistor to change between a conduction state and a non-conduction state, and a selection transistor configured to switch between a source of the drive transistor and a data line to change between a conduction state and a non-conduction state, the element selection line is a first element selection line connected to a gate of the holding transistor, and the second element selection line is connected to a gate of the selection transistor and configured to enable application of a level different from a level of the first element selection line.

11. The thin film transistor array device according to claim 10, further comprising:
a second block selection circuit including a plurality of second block selection lines each corresponding to a respective one of the second blocks,
wherein the row block is a first block, the selection row is a first selection row, the row block selection line is a first block selection line, the row block selection circuit is a first block selection circuit, the switching circuit is a first switching circuit, the second block is provided in a plurality such that the plurality of second blocks each includes a plurality of second selection rows each having the element circuit and a second element selection line connected to a gate of the selection transistor, all the second element selection lines in the respective one of the second blocks are parallelly connected to the second block selection line, the second block selection circuit is configured to apply, to the second block selection lines one by one, a selection level for selecting one second block from the second blocks from outside, the one second block has the element circuit that is the same as the element circuit in the first block selected by the first block selection circuit, the second block selection circuit further includes a second switching circuit configured to switch between the second element selection line and the second block selection line to change between a conduction state and a non-conduction state simultaneously for all the second element selection lines, and the second switching circuit is configured to permit second-block basis driving in the conduction state such that all the element circuits in the one second block selected are targeted to be simultaneously driven, and to permit second-row basis driving in the non-conduction state such that the second-block basis driving is prohibited and that all the element circuits in one of the second selection rows are simultaneously driven.

12. An EL device, comprising:
the thin film transistor array device of claim 2 including a plurality of element circuits each including the thin film transistor and an EL element.

13. A sensor device, comprising:
the thin film transistor array device of claim 2 including a plurality of element circuits each including the thin film transistor and a sensor element.

14. An EL device, comprising:
the thin film transistor array device of claim 3 including a plurality of element circuits each including the thin film transistor and an EL element.

15. A sensor device, comprising:
the thin film transistor array device of claim 3 including a plurality of element circuits each including the thin film transistor and a sensor element.

16. An EL device, comprising:
the thin film transistor array device of claim 4 including a plurality of element circuits each including the thin film transistor and an EL element.

17. A sensor device, comprising:
the thin film transistor array device of claim 4 including a plurality of element circuits each including the thin film transistor and a sensor element.

18. A method for driving a thin film transistor array device, comprising:
driving a switching circuit such that conduction is established between a row block selection line and an element selection line for all element selection lines; and
applying, to a plurality of row block selection lines one by one, a selection level for selecting one row block from a plurality of row blocks such that a row block selection circuit simultaneously selects all element circuits in the one row block selected through application of the selection level,
wherein the thin film transistor array device comprises a plurality of row blocks each including a plurality of selection rows such that each of the selection rows has at least one element circuit including a thin film transistor, and one element selection line connected to a gate of the thin film transistor, and a row block selection circuit including a plurality of row block selection lines each corresponding to a respective one of the row blocks such that all the element selection lines in the respective one of the row blocks are parallelly connected to a respective one of the row block selection lines, and the row block selection circuit includes a switching circuit configured to switch between the row block selection line and the element selection line to change between a conduction state and a non-conduction state simultaneously for all the element selection lines.

19. The method for driving a thin film transistor array device according to claim 18, wherein the thin film transistor array device includes a plurality of element circuits each including the thin film transistor and an EL element, and the thin film transistor array device comprises an EL device comprising the plurality of row blocks each including the plurality of selection rows each having the at least one element circuit including the EL element and the thin film transistor, and the element selection line connected to the gate of the thin film transistor.

20. A method for driving a thin film transistor array device according to claim 18, wherein the thin film transistor array device includes a plurality of element circuits each including the thin film transistor and a sensor element, and the thin film transistor array device comprises a sensor device comprising the plurality of row blocks each including the plurality of selection rows each having the at least one element circuit including the sensor element and the thin film transistor, and the element selection line connected to the gate of the thin film transistor.
